(19) United States
(12) Patent Application Publication
(10) Pub. No.: US 2025/0290984 A1
(43) Pub. Date: Sep. 18, 2025

(54) SYSTEM AND METHOD FOR STATE-OF-POWER ESTIMATION OF A BATTERY USING IMPEDANCE MEASUREMENTS

(71) Applicant: Analog Devices, Inc., Wilmington, MA (US)

(72) Inventors: Johannes Traa, Medford, MA (US); Omer Tanovic, Acton, MA (US); Hemtej Gullapalli, Littleton, MA (US)

(21) Appl. No.: 18/861,499

(22) PCT Filed: Apr. 28, 2023
(86) PCT No.: PCT/US2023/066370

§ 371 Date: Oct. 29, 2024

Related U.S. Application Data
(60) Provisional application No. 63/336,724, filed on Apr. 29, 2022.

(51) Int. Cl. G01R 31/367; B60L 58/18; G01R 31/3842; G01R 31/389; G01R 31/396

(52) U.S. Cl. CPC G01R 31/367; B60L 58/18; G01R 31/3842; G01R 31/389; G01R 31/396

(57) ABSTRACT

A method is provided for pretraining a hyper model configured for use in predicting a state of power (SoP) of a vehicle battery. The method includes performing electrochemical impedance spectroscopy (EIS) scans on a plurality of batteries having a set of similar operating characteristics to the vehicle battery. The EIS scans are performed across various states of the vehicle battery. The method further includes fitting parameters of the hyper model by applying an optimization technique to results of the EIS scans. The hyper model includes a family of models that each define a voltage response of a respective cell from among a plurality of cells of the vehicle battery to a current profile over the various states of the vehicle battery.

### CROSS REFERENCE TO RELATED APPLICATION

This application is a non-provisional utility patent application based on U.S. Provisional Application Ser. No. 63/336,724, entitled “SYSTEM AND METHOD FOR STATE-OF-POWER ESTIMATION OF A BATTERY USING IMPEDANCE MEASUREMENTS”, filed on Apr. 29, 2022, the disclosure of which is incorporated herein by reference in its entirety.

### FIELD OF THE DISCLOSURE

This disclosure relates generally to battery monitoring and, more particularly, to a system and method for estimating battery state of power (SoP) using battery impedance measurements.

As the development of electric vehicles grows at rapid pace, battery management systems (BMS) are expected to track the state of battery packs to enable effective operation of the corresponding control algorithms. One such state to monitor is the maximum amount of power that can be drawn from (during rapid acceleration) or put back (during regenerative breaking) into the pack, which translates directly to vehicle performance and user experience. Currently, BMS' use simplistic and conservative estimates computed as the product of the minimal terminal voltage with the maximum current that can be drawn from it for a given period of time. However, this significantly underestimates the maximal power metric.

State of Power (SoP) quantifies the maximum amount of power that a battery can deliver over a short period of time. Traditional battery management systems infer SoP-like information by training a model based on time-domain voltage and current data, often in the form of a current pulse schedule (i.e., Direct Current Internal Resistance (DCIR) measurements), where SoP estimation is accomplished through lengthy DCIR measurement tests involving current pulses with long relaxation times. This can be very time-consuming and is impractical for several reasons, one being that the resulting equivalent circuit model (ECM) must be recalibrated after the cell has aged somewhat. Thus, there is a need for improved SoP measurement and improved ECM recalibration.

### SUMMARY

The following presents a simplified summary of one or more aspects in order to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

In this exposition we define a hyper model as a family of models that each characterize the voltage response of a respective cell from among a plurality of cells of the vehicle battery to a current profile under varying battery states. Thus, for any given battery state, we have an equivalent state space model that represents the electrical characteristics of the battery accurately. According to an aspect, a method is provided for pretraining a hyper model that may be used to predict the state of power (SoP) of a vehicle battery. The method includes performing electrochemical impedance spectroscopy (EIS) scans on a plurality of batteries similar to the vehicle battery under various states of the battery. In one aspect, the various battery states can include at least some of different temperature ranges, different states of charge (SoCs), age of the battery, and the nature of the current load the battery is subjected to. The method further includes fitting parameters of the hyper model by applying an optimization technique to results of the EIS scans.

According to another aspect, a method is provided for predicting a state of power (SoP) of a battery. The method includes performing a plurality of electrochemical impedance spectroscopy (EIS) scans on the battery prior to an initial use of the battery in a vehicle. The method further includes calibrating a pretrained hyper model using results of the EIS scans. The pretrained hyper model includes a family of models that each define a voltage response of a respective cell from among a plurality of cells of the battery to a current profile over various states of the battery. The method further includes performing a plurality of additional EIS scans on the battery subsequent to the initial use of the battery in the vehicle. The method also includes recalibrating the pretrained hyper model using results of the additional EIS scans.

According to a further aspect, a system is provided for predicting a state of power (SoP) of a battery. The system includes an electrochemical impedance spectroscopy (EIS) system for performing a plurality of EIS scans on the battery prior to an initial use of the battery in a vehicle, and a plurality of additional EIS scans on the battery subsequent to the initial use of the battery in the vehicle. The system further includes a memory device for storing program code. The system also includes a processing device operatively coupled to the EIS system and the memory device for running the program code to calibrate a pretrained hyper model using results of the plurality of EIS scans. The pretrained hyper model includes a family of models that each define a voltage response of a respective cell from among a plurality of cells of the battery to a current profile over various states of the battery. The processor device additionally runs the program code to recalibrate the pretrained hyper model using results of the plurality of additional EIS scans.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, wherein dashed lines may indicate optional elements, and in which:

FIG. 1 is a diagram of a battery system within a vehicle, in accordance with an exemplary aspect;

FIG. 2 is a schematic diagram showing a battery equivalent circuit model (ECM), in accordance with an exemplary aspect;

FIG. 3 is a diagram showing an example Nyquist plot of the negative of the imaginary part of the EIS versus real part of the impedance, showing the measured impedance and that estimated from the ECM of FIG. 2 for a battery, in accordance with an exemplary aspect;

FIG. 4 is a diagram showing a plot of terminal voltage versus time for the battery ECM of FIG. 2, in accordance with an exemplary aspect;

FIG. 5 is a schematic diagram showing another battery ECM, in accordance with an exemplary aspect;

FIGS. 6-8 and 10-11 are plots showing the estimated parameters of the ECM in FIG. 5 computed using non-linear least squares (NLLS) as a function of states of charge (SoC) and temperature (T), in accordance with an exemplary aspect;

FIG. 9 is a diagram showing the Nyquist plots of the negative of the imaginary part of the cell impedance versus the real part of the cell impedance;

FIG. 12 is a plot of open circuit voltage (OCV) versus SoC, in accordance with an exemplary aspect;

FIG. 13 is a diagram showing an extended Kalman Filter (EKF) functioning, in accordance with an exemplary aspect;

FIG. 14 is a block diagram showing a key-off use case, in accordance with an exemplary aspect;

FIG. 15 is a block diagram showing a key-on use case, in accordance with an exemplary aspect;

FIG. 16 is a diagram showing a plot of current versus time for the battery ECM of FIG. 2;

FIG. 17 is a diagram showing a plot of voltage versus time for the battery ECM of FIG. 2;

FIG. 18 is a flow diagram illustrating a method for offline pretraining of hyper model parameters, in accordance with an exemplary aspect;

FIG. 19 is a flow diagram showing a method for calibration and recalibration of a new cell, in accordance with an exemplary aspect; and

FIGS. 20-21 are flow diagrams further showing a step the method of FIG. 19, in accordance with an exemplary aspect.

### DETAILED DESCRIPTION OF EXAMPLE EMBODIMENTS

In various aspects, systems and methods are provided for estimating the state of power (SoP) of a battery using electrochemical impedance spectroscopy (EIS) measurement technology. In various aspects, the battery state of power (SoP) is estimated using impedance measurements taken at multiple frequencies. Battery SoP is defined as the maximal power that battery can generate or absorb at any point in time without exceeding manufacturers limits, such as those on maximal current, maximal and minimal terminal voltage and temperature, etc. In various aspects, the impedance measurements may be used to train a family of equivalent circuit models (ECM), labeled an “ECM hyper model”. The hyper model defines the voltage response of each cell to a respective current profile throughout varying conditions (for example, varying combinations of temperatures and states of charge, or in another example, varying combinations of ages of the cell). When the cell is in operation, the model is used to track the internal state of the cell, giving access to a SoP estimate of that cell at any point in time through a prediction mechanism. Alternatively, a static model can be defined for relevant inputs that are measured in situ.

Thus, the hyper model may be an equivalent circuit model (ECM) that may map various resistive and capacitive components of the ECM to the varying combinations of temperatures and states of charge used in the EIS scans. While one or more aspects may be directed to the use of a battery equivalent circuit model (ECM) to model a battery, other representations can be used such as, for example, and not limited to, a model reduced from a physics based model that maps physics representations of battery elements to various combinations of temperatures and states of charge used in the EIS scans, and so forth. It is to be appreciated that aspects of the present disclosure may use any type of battery model to obtain a SoP estimate in accordance with the present disclosure.

Aspects described herein are designed to report how much power a battery can generate or absorb at any point in time using information from electrochemical impedance spectroscopy (EIS) because exceeding certain limits on the power applied to/from an EV battery during charge/discharge can lead to premature aging, electrochemical faults, or serious problems like thermal runaway. Additionally, traditional BMS systems infer SoP-like information by training a model based on time-domain voltage and current data, often in the form of a current pulse schedule (i.e., Direct Current Internal Resistance (DCIR) measurement). In another example, traditional BMS systems infer SoP-like information by training a model based on time-domain voltage and current data from hybrid pulse power characterization (HPPC) current schedules. Moreover, EIS scan measurements enable more complete and precise modeling of a battery's behavior by training models on impedance spectra.

EIS is an emerging technology in Battery Management Systems (BMS′). In EIS, a cell is stimulated with a sinusoidal current and the resulting voltage is measured (or vice versa). This is repeated at many different frequencies to produce an impedance spectrum that can be used to fit models characterizing the electrochemical properties of the cell.

Aspects described herein include collecting impedance spectra while a car is at rest (“key-off”) at various state-of-charge (SoC) levels and temperatures and using this data to train a family of equivalent circuit models (ECM), referred to herein as an “ECM hyper model”. Impedance spectra measurements can also be collected on a corpus of batteries before they are placed in the car, while the in situ measurements (“key-off”) are then used to calibrate the model. The hyper model defines the voltage response of the cell to a current profile throughout varying conditions. When the cell is in use, the model is used to track the internal state of the cell, enabling SoP estimation at any point in time through a prediction mechanism. Alternatively, a static model can be defined for relevant inputs that are measured in situ.

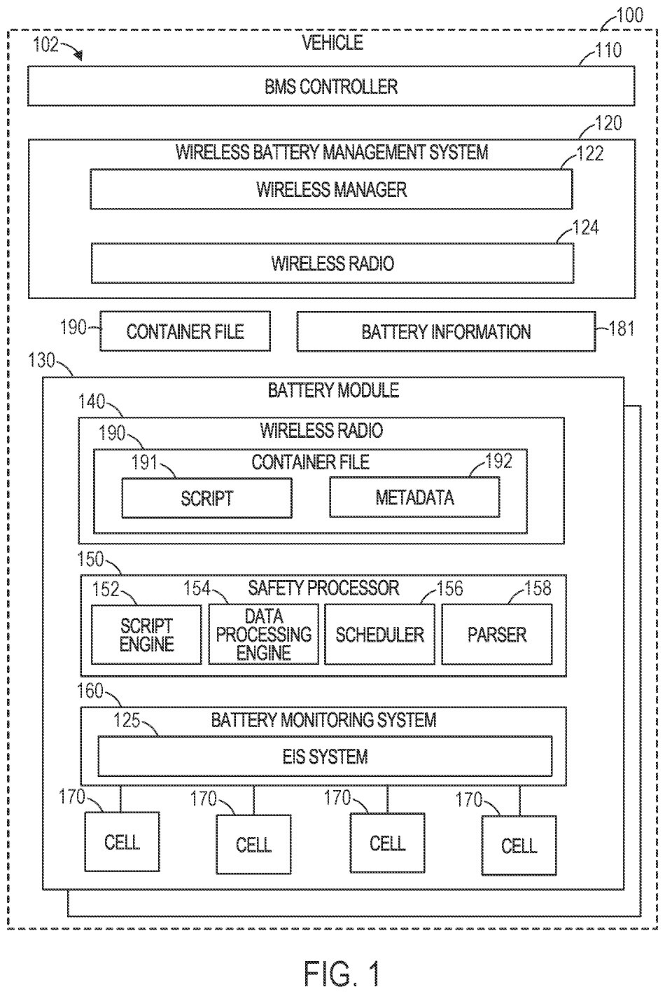

SoP estimation can be accomplished through lengthy DCIR tests involving current pulses with long relaxation times. This can be very time-consuming and is impractical for several reasons, one being that the resulting ECM must be calibrated after the cell has aged somewhat. The use of EIS spectra is much more practical because it is relatively fast and does not involve stimulating the cell with a large current pulse. Recalibration of the ECM throughout the life of the cell is much easier because EIS measurements may be taken while the car is at rest (a.k.a., “key-off”). The concept of EIS-based ECMs for SoP estimation is represented in FIGS. 1-4.

Referring to FIG. 1, a battery system 102 within a vehicle 100 is shown. The vehicle 100 may be an electric vehicle (EV) or a hybrid vehicle such as a plug-in hybrid electric vehicle. The vehicle 100 may be considered a host of the battery system 102. The battery system 102 may include a BMS controller 110, a wireless battery management system (wBMS) 120, and a plurality of battery modules 130.

The BMS controller 110 may be a component of the vehicle 100 configured to interface with the wBMS 120. For example, the BMS controller 110 may be an electronic control unit (ECU) of the vehicle 100. The BMS controller 110 may execute a BMS controller application, which may be referred to as a safety application. For instance, the BMS controller 110 may communicate with the wBMS 120 to receive information about the battery system such as state of charge, voltage, temperatures, and any faults that have occurred. The BMS controller 110 may also communicate with other vehicle components such as an inverter or charger.

The wBMS 120 may be configured to interface between the battery modules 130 and the BMS controller 110. For example, the wBMS 120 may receive packets including measurement messages and fault messages from the battery modules 130. The wBMS 120 may aggregate the messages from the individual battery modules to provide system level information to the BMS controller 110. The wBMS 120 may include a wireless manager 122 and a wireless radio 124. The wireless manager 122 may be configured to generate messages for transmission to the battery modules 130 and receive messages from the battery modules 130. The wireless manager 122 may include a radio protocol stack. The wireless radio 124 may include one or more radios configured to transmit radio-frequency (RF) signals to the battery modules 130. The wireless radio 124 may be referred to as a head radio and may control (e.g., schedule) the communications with the battery modules 130.

The battery module 130 may include a wireless radio 140, a safety processor 150, a battery monitoring system 160, and a plurality of cells 170. The cells 170 may be battery cells that store power. In some implementations, each battery module 130 may include between 3 and 24 individual cells 170.

The battery monitoring system 160 may be configured to monitor one or more parameters of the plurality of battery cells. For example, the battery monitoring system 160 may monitor voltage and temperature of each cell. The battery monitoring system 160 may provide the measurements to the safety processor 150. The battery monitoring system 160 may be referred to as a battery monitoring integrated circuit (BMIC).

In various aspects, battery monitoring system 160 includes an electrochemical impedance spectroscopy (EIS) system 125 for taking EIS measurements at various frequencies. The measurements may include, among other variables, voltage and current from which an impedance spectrum of each cell can be calculated. Such calculation can be performed by the safety processor 150 in order to calculate SoP using the measurements to control how the battery is used. In this way, premature battery damage among other issues can be avoided.

The safety processor 150 may be a computer processor configured to execute computer code such as a script. In some implementations, the safety processor 150 is a separate processor connected to the wireless radio 140 and the battery monitoring system 160 via interfaces such as a serial peripheral interface (SPI). In other implementations, the safety processor may be a processor of the wireless radio 140. The safety processor 150 may be configured to perform various tasks with respect to managing the battery module 130. For example, the safety processor 150 may be configured to execute a battery monitoring script to generate a battery information payload defined by a battery information payload format. The battery information payload may be based on the SoP calculated using the EIS measurements from the EIS system 125. The safety processor may also receive commands (e.g., a cell balancing command) from the wBMS 120, and write commands to the battery monitoring system 160. The safety processor 150 may include a script engine 152, a data processing engine 154, a scheduler 156, and a parser. The script engine 152 may execute a script 191 received from wBMS 120. The data processing engine 154 may perform data processing commands defined by the script to write commands to the battery monitoring system 160 and process data received from the battery monitoring system 160. In some implementations, the data processing engine may be a component of the script engine. The scheduler 156 may be configured to generate a plurality of packets according to a battery information payload format. For example, the scheduler 156 may operate according to an initialization schedule at initialization to potentially generate fault packs and operate according to an active mode schedule to generate measurement messages within a timed subloop. The parser 158 may be configured to parse various components of the script.

The wireless radio 140 may be configured to communicate with the wBMS 120 and/or a service device. The wireless radio 140 may be a radio similar to the wireless radio 124 configured to transmit and receive RF signals. The wireless radio 140 may be referred to a tail radio because the wireless radio 140 may be managed by the wireless radio 124. The wireless radio 140 is configured to receive a container file 190 from the wBMS 120. The container file 190 includes metadata 192 defining the battery information payload format and the battery monitoring script. The wireless radio 140 is configured to transmit at least the metadata 192 of the container file 190 to the service device. The wireless radio 140 is also configured to transmit packets 181 including a battery information payload to either the wBMS 120 or the service device.

To calculate SoP, a model of the battery is used. In some aspects, the model is a battery equivalent circuit model (ECM). In other aspects, the model is a model reduced from a physics-based model. Other model representations of a battery can also be used, while maintaining the spirit of the present disclosure.

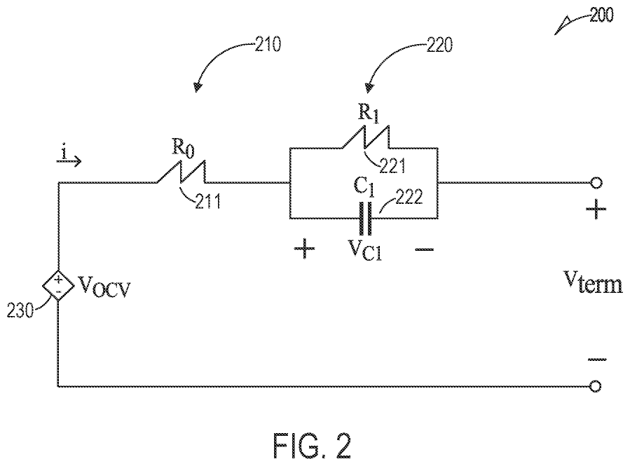

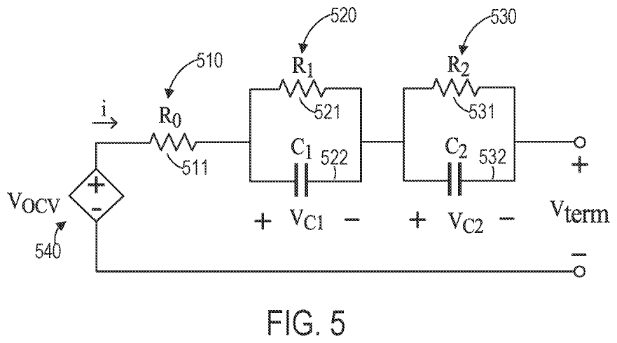

Referring to FIG. 2, a battery equivalent circuit model (ECM) 200 is shown, in accordance with an exemplary aspect. The battery ECM 200 includes an R section 210 and an RC section 220. While one RC section 220 is shown, other circuit models can have more than one RC section 220, as shown in FIG. 5.

The R section 210 of ECM 200 includes resistor R₀ 211. The RC section 220 includes resistor R₁ 221 and capacitor C₁ 222 in parallel and having voltage V_{C1} across them. A positive terminal of a voltage V_{OCV} 230 is connected to one side the resistor R₀ 211. A positive terminal of a battery terminal voltage Vₜₑᵣₘ is connected to one side of the RC section 220. The other side of RC section 220 is connected to another side of the resister R₀ 211. A negative terminal of the battery terminal voltage Vₜₑᵣₘ is connected to a negative terminal of the voltage V_{OCV} 230.

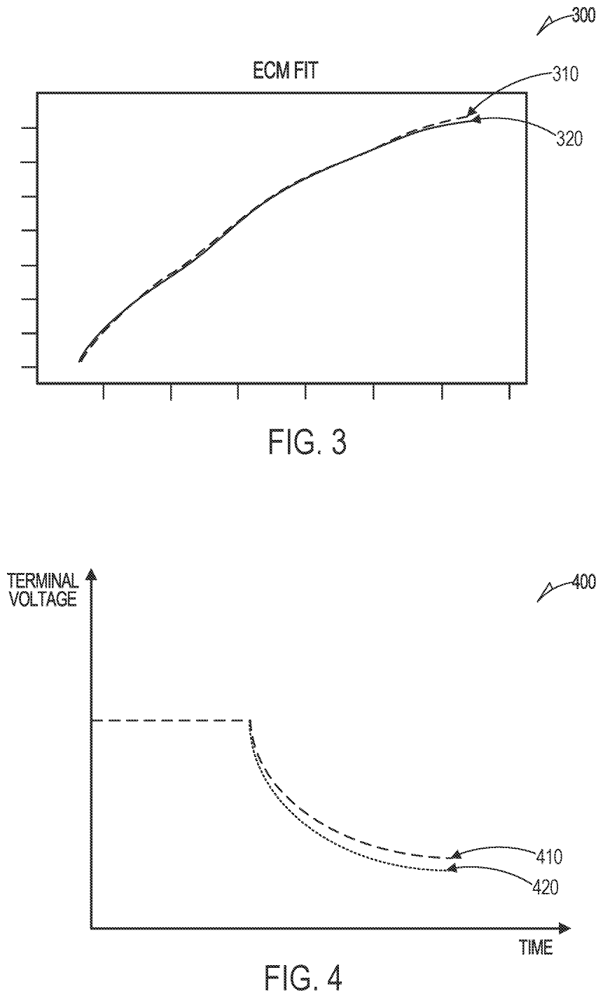

Referring to FIG. 3, a Nyquist plot 300 of the negative of the imaginary part of the electrochemical impedance spectrum of a battery versus the real part of the impedance for the battery ECM 200 of FIG. 2 is shown, in accordance with an exemplary aspect. Curve 310 denotes impedance as computed using the estimated ECM model of the battery and curve 320 denotes the measured impedance of the battery.

Referring to FIG. 4, a plot 400 of terminal voltage versus time for the battery ECM 200 of FIG. 2 is shown, in accordance with an exemplary aspect. In particular, time is shown in the x-axis and terminal voltage (Vₜₑᵣₘ) is shown in the y axis. Two curves are shown, a predicted curve 420 and a true curve 410.

Referring to FIG. 5, another battery equivalent circuit model (ECM) 500 is shown, in accordance with an exemplary aspect. The battery ECM 500 can be used to accommodate edge devices, e.g., in a wireless BMS such as that shown and described with respect to FIG. 1. The battery ECM 500 includes an R section 510, a first RC section 520, and a second RC section 530. The R section 510 includes resistor R₀ 511. The first RC section 520 includes resistor R₁ 521 and capacitor C₁ 522 in parallel and having voltage V_{C1} across them. The second RC section 530 includes resistor R₂ 531 and capacitor C₂ 532 in parallel and having voltage Vc₂ across them. A positive terminal of a voltage V_{OCV} 540 is connected to one side of the resistor R₀ 511. A positive terminal of a battery terminal voltage Vₜₑᵣₘ Is connected to one side of the second RC section 530. The other side of the second RC section 530 is connected to another side of first RC section 520. The other side of first RC section 520 is connected to another side of the resister R₀ 511. A negative terminal of the battery terminal voltage Vₜₑᵣₘ is connected to a negative terminal of the voltage V_{OCV} 540.

For the ECM 500 of FIG. 5, battery impedance is given by the following:

$$\hat{Z} ( ω ) = {R}_{0} + {\sum }_{i} \frac{1}{\frac{1}{{R}_{i}} + j ω {C}_{i}} \qquad ( 1 )$$

$$= {R}_{0} + {\sum }_{i} \frac{{R}_{i}}{1 + j ω {R}_{i} {C}_{i}} \qquad ( 2 )$$

$$= {R}_{0} + {\sum }_{i} \frac{{R}_{i}}{1 + j ω {R}_{i} {C}_{i}} \cdot \frac{1 - j ω {R}_{i} {C}_{i}}{1 - j ω {R}_{i} {C}_{i}} \qquad ( 3 )$$

$$= [ {R}_{0} + {\sum }_{i} \frac{{R}_{i}}{1 + {ω}^{2} {R}_{i}^{2} {C}_{i}^{2}} ] + j [ - {\sum }_{i} \frac{ω {R}_{i}^{2} {C}_{i}}{1 + {ω}^{2} {R}_{i}^{2} {C}_{i}^{2}} ] \qquad ( 4 )$$

Using EIS, this impedance is measured at various radial frequencies (ωₖ) and the ECM can be inferred from the constrained non-linear least squares estimate of the parameters.

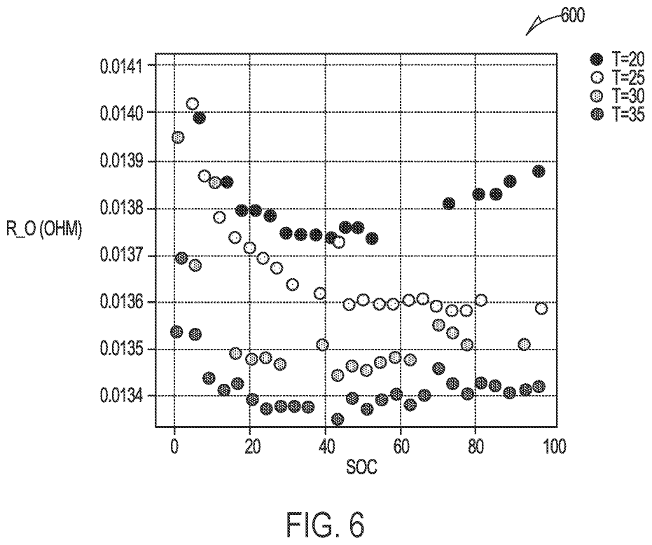

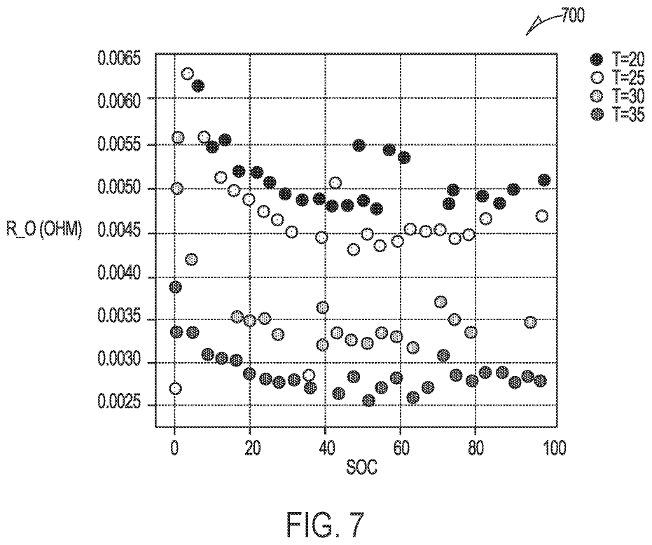

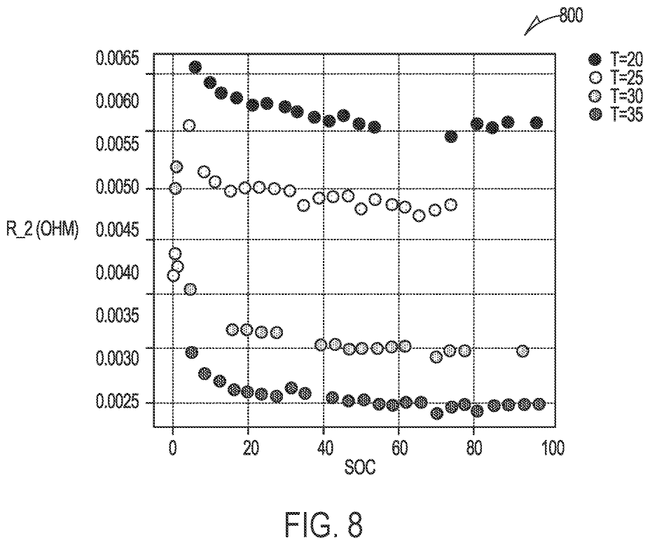

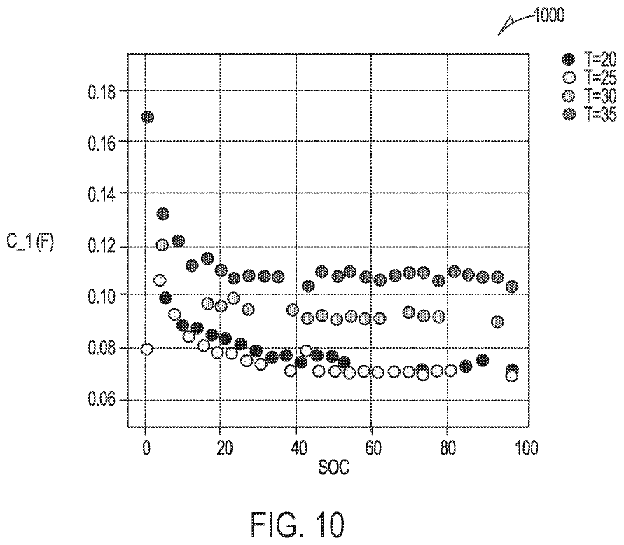

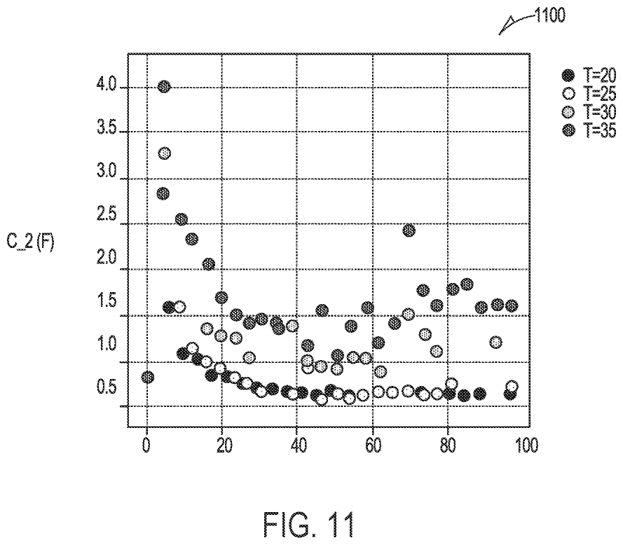

Referring to FIGS. 6-8 and FIGS. 10-11, estimates of ECM parameters as a function of temperature and state of charge (SoC) for an R-RC-RC approximation of a 3Ah Li-ion battery are shown. The estimates were derived using EIS sweeps made at different temperatures and SoCs.

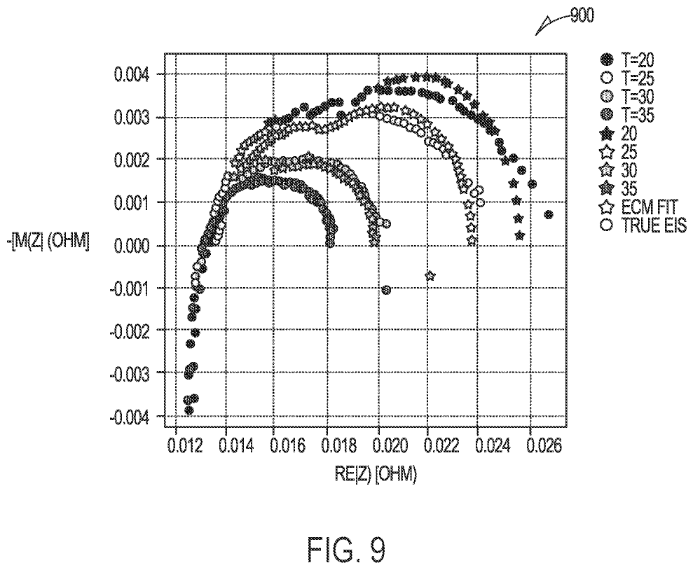

The plot in FIG. 9, shows the estimated battery impedance (the Nyquist plot) in comparison to the measured EIS at various temperatures at 50% SoC. This clearly shows that the estimated ECM approximates the battery impedance well. In particular, FIG. 9 shows the Nyquist plots of the negative of the imaginary part of the cell impedance versus the real part of the cell impedance which, in turn, shows the comparison of the measured impedance through EIS and that estimated from the ECM of FIG. 4 where estimated parameters of the ECM in FIG. 5 were computed using non-linear least squares (NLLS) as a function of temperature (T), in accordance with an exemplary aspect;

EIS analysis uses a computer to find the model parameters that give the best agreement between a model's impedance spectrum and a measured spectrum. A non-linear least squares fitting (NLLS) algorithm may be used. NLLS starts with initial estimates for all the model's parameters. Starting from this initial point, the algorithm makes changes in several or all of the parameter values and evaluates the resulting fit. If the change improves the fit, the new parameter value is accepted. If the change worsens the fit, the old parameter value is retained. Next, a different parameter value is changed and the test is repeated. Each trial with new values is called an iteration. Iterations continue until the goodness of fit exceeds an acceptance criterion, or until the number of iterations reaches a limit.

FIGS. 6-11 show an ECM fit using NLLS as a function of SoC and temperature, and also show that the circuit parameters are a function of the battery state (T, SoC, Age). For instance, the cell resistances decrease with increasing temperature, whereas the opposite is broadly true of the capacitances. To account for this variation, it is possible to infer an equivalent hyper model of a battery which maps the battery state to the ECM such as the following:

$${R}_{i} = {f}_{R} ( T , SoC ; {θ}_{i} ) ,$$

$${C}_{i} = {f}_{C} ( T , SoC ; {ϕ}_{i} ) .$$

Such a hyper model also helps us interpolate effectively across different battery states without requiring explicit experimentation.

Alternatively, projected gradient descent may be used to track the ECM parameters by using EIS measurements. The gradients for the algorithm may be derived based on the partial derivatives of the estimate \hat{Z} as follows:

$$\frac{\partial \hat{Z}}{\partial {R}_{0}} = 1 , \frac{\partial \hat{Z}}{\partial {R}_{i}} = \frac{( 1 - {ω}^{2} {R}_{i}^{2} {C}_{i}^{2} - j ( 2 ω {R}_{i} {C}_{i} ) )}{1 + {ω}^{2} {R}_{i}^{2} {C}_{i}^{2}} ,$$

$$\frac{\partial \hat{Z}}{\partial {C}_{i}} = - \frac{ω {R}_{i}^{2}}{1 + {ω}^{2} {R}_{i}^{2} {C}_{i}^{2}} ( 2 ω {R}_{i} {C}_{i} + j ( 1 - {ω}^{2} {R}_{i}^{2} {C}_{i}^{2} ) ) .$$

A time-domain voltage prediction technique will now be described, in accordance with an exemplary aspect, according to an exemplary aspect. To track the cell terminal voltage, the mathematical model is first derived as a function of the ECM parameters and the current applied to the battery as follows:

$${V}_{term} ( t ) = {V}_{OCV ( t )} - {R}_{0} i ( t ) - {\sum }_{i} {V}_{{C}_{i}} ( t ) .$$

Here, the component voltage dynamics are described by the following:

$${\dot{V}}_{{C}_{i}} ( t ) = - \frac{1}{{τ}_{i}} {v}_{{C}_{i}} ( t ) + \frac{{R}_{i}}{{τ}_{i}} i ( t ) .$$

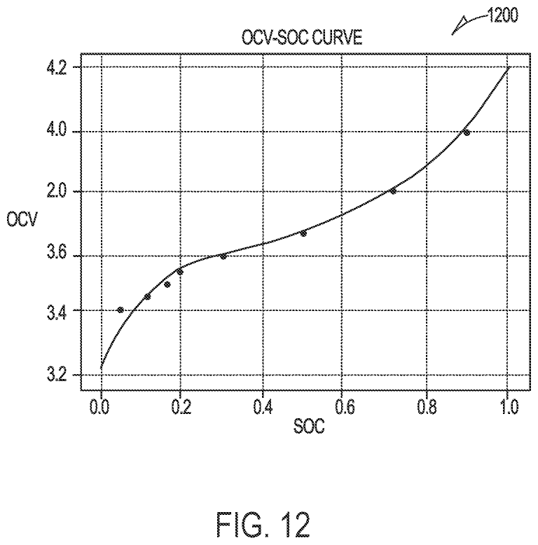

Thus, tracking Vₜₑᵣₘ equivalently translates to tracking the OCV and V_{C}_{ᵢ}. The OCV is typically a non-linear function of the SoC, such as shown in FIG. 12 which shows the OCV-SoC for a battery, and the SoC (s(t)) evolves as follows:

$$s ( t ) = - \frac{i ( t )}{cap}$$

where cap is the battery capacity. The ECM parameters also vary as non-linear functions of the battery state. Accounting for these, an Extended Kalman Filter (EKF) is described to track Vₜₑᵣₘ.

A description will now be given regarding EKF-based terminal voltage tracking, in accordance with an exemplary aspect.

The EKF technique includes forming battery system matrices expressed as a function of a step index that is dependent on parameters of the hyper model that, in turn, are dependent on the varying conditions.

Discretizing the differential equations, the state space model for the ECM 500 in FIG. 5 is given by the following:

$$x [ n ] = [ \begin{matrix}s [ n ] \\ {V}_{{C}_{1}} [ n ] \\ {V}_{{C}_{2}} [ n ]\end{matrix} ] = [ \begin{matrix}1 & 0 & 0 \\ 0 & 1 - {a}_{1} & 0 \\ 0 & 0 & 1 - {a}_{2}\end{matrix} ] [ \begin{matrix}s [ n - 1 ] \\ {V}_{{C}_{1}} [ n - 1 ] \\ {V}_{{C}_{2}} [ n - 1 ]\end{matrix} ] + [ \begin{matrix}- Δ t / cap \\ {a}_{1} {R}_{1} \\ {a}_{2} {R}_{2}\end{matrix} ] i [ n - 1 ] .$$

where

$${a}_{i} = \frac{Δ t}{{R}_{i} {C}_{i}} .$$

The measurement is given by the following:

$$y [ n ] = {V}_{term} [ n ] = {V}_{OCV} [ n ] ( [ \begin{matrix}1 & 0 & 0\end{matrix} ] x [ n ] ) - [ \begin{matrix}0 & 1 & 1\end{matrix} ] x [ n ] - {R}_{0} i [ n ] .$$

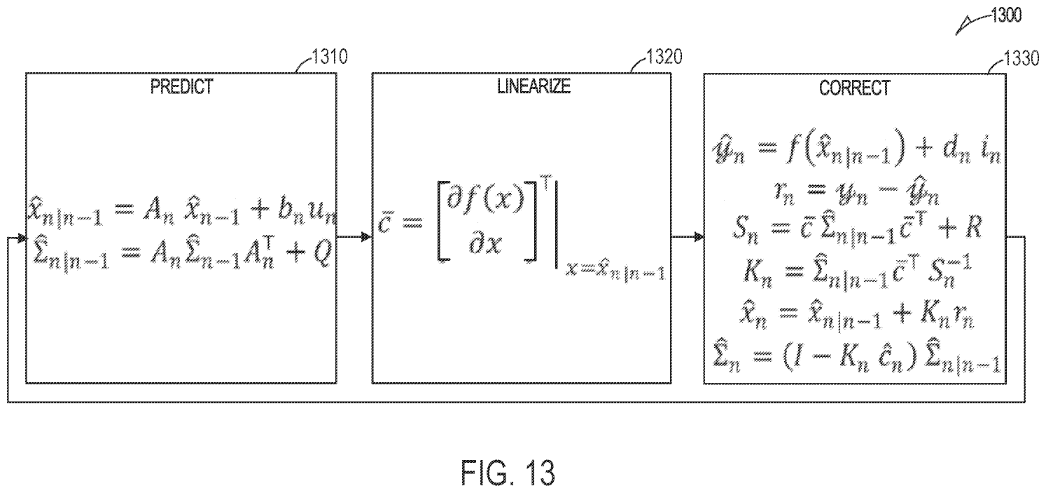

Thus, state estimates are corrected when Vₜₑᵣₘ measurements are available, and when Vₜₑᵣₘ measurements are unavailable, the state vector can be predicted using the state space model. Consider the state and measurement models as follows:

$$\begin{matrix}{x}_{n} = {A}_{n} {x}_{n - 1} + {b}_{n} {i}_{n - 1} + {ϵ}_{n} , \\ {y}_{n} = f ( {x}_{n} ) + {d}_{n} {i}_{n} + {δ}_{n} ,\end{matrix}$$

where the noise processes are normal random vectors given by ∈ₙ˜N(0, Q), δₙ˜N(0, R). Then an EKF, functioning 1300 as shown in FIG. 13, can track the terminal voltage of the battery.

The EKF functioning 1300 includes a predict portion 1310, a linearize portion 1320, and a correct portion 1330.

It may be noted here that alternate approaches other than an EKF can be used to track and predict the battery state including adaptive filtering and autoregressive models that predict the terminal voltage of the battery given the current state of the system. The methodology described here to compute the state of power using the hyper model of a battery is compatible with any such method.

A description will now be given regarding estimating the SoP of a battery, in accordance with an exemplary aspect.

The SoP of a battery measures the maximum amount of power that can be delivered by the battery. Here, two possible definitions are described and methods to calculate the SoP. One definition is referred to as constant current SoP, and the other definition is referred to as constant power SoP.

Regarding constant current SoP, a conservative estimate of the maximal power that can be drawn from the battery may be defined as follows:

P=V_{term,min}iₘₐₓ,

where iₘₐₓ is the maximum current pulse that can be drawn from the battery. The idea is that the maximal cell current constrained by the minimum terminal voltage, V_{term,min} results in the maximal power that can be drawn from the battery.

Let Vₜₑᵣₘ(i, t+Tₚ) be the terminal voltage estimate as a function of current i, over time, where T, is the time period over which SoP is to be computed. Then, the maximum value of i is the solution to the following:

$${V}_{term} ( i , t + {T}_{p} ) - {V}_{term , min} = 0.$$

In an aspect, the Newton-Raphson method can be used to find the root of this equation, and hence compute the SoP. This however is a conservative estimate as it does not account for instantaneous power fluctuations on account of the variation in Vₜₑᵣₘ.

Regarding constant power SoP, the maximal constant power that can be drawn from a battery amounts to more net energy output than the constant current estimate as it adapts to the variation in Vₜₑᵣₘ. Thus, a more accurate estimate of the maximal energy that can be drawn from a battery is derived by solving for the instantaneous currents that results in a constant power Pₘₐₓ over the time period T, of interest. This power is computed by using Powell's conjugate direction method while constraining i, Vₜₑᵣₘ to the safety limits of the battery

Unlike aspects described herein, conventional techniques for fitting ECMs and corresponding methods are current pulse-based measurement techniques.

In accordance with features of aspects described herein, EIS measurements may be used for training of parameters of a general-purpose algorithmic model to be used for in-situ (while an electric vehicle (EV) is in-use) SoP prediction. Additionally, EIS measurements are used at key-off (for example, when an EV is parked in a garage) to recalibrate parameters of the SoP algorithmic model. Moreover, EIS measurements are used during EV in-use scenario to dynamically recalibrate parameters of the SoP model.

A primary purpose of aspects described herein is to estimate how much power a cell can output at any given time. SoP can be quantified indirectly as the maximum allowable static current that can be sustained for Δt seconds (or some prespecified time period). “Maximum allowable” is defined as the largest current that does not cause a constraint violation. Constraints can be defined for terminal voltage, current, state-of-charge, cell temperature, etc. Alternatively, SoP can be quantified indirectly as the maximum allowable static current that can be sustained for Δt seconds (or some prespecified time period). “Maximum allowable” is defined as desired, e.g., an amount that does not result in a temporary loss of capacity of more than a specified fraction (e.g., 5%). SoP (or max allowable current) is a dynamic variable and depends on the initial state of the battery at the moment of prediction. In other words, any system that maps measurable parameters to SoP would need to include memory in order to achieve acceptable accuracy, unless battery state is supplied as an additional input.

SoP estimation use cases include key-off and key-on. For key-off, a model is developed that generates a prediction of SoP for an a priori given “battery state.” Battery state could be defined, for example, as the most recent battery current, terminal voltage, open circuit voltage (OCV), state of charge (SoC), temperature, and impedance measurement (this might be different for individual batteries and the whole pack). The SoP model is a multidimensional look-up table that maps each expected battery state into a corresponding SoP value (could also be implemented as a function that performs this mapping/calculation when called—that is, not necessarily a hard encoded table that is just read from memory when called).

For the key-on use case, the model may be equipped with a tracker which starts from a known initial condition and then tracks “battery state.” Whenever SoP prediction is needed, the model can use the most recent battery state supplied by the tracker. The SoP output of the model is instantaneous (i.e., evaluated in real-time) and provides a prediction for the current state of the battery only.

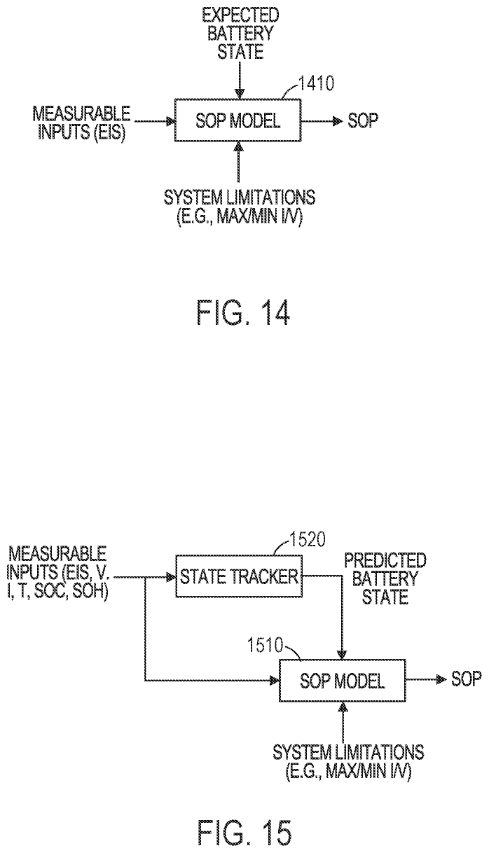

Referring to FIG. 14 a key-off use case 1400 is shown, in accordance with an exemplary aspect. The key-off use case 1400 involves a State of Power (SoP) model 1410 which inputs measurable inputs (EIS), expected battery state, and system limitations (e.g., maximum/minimum current/voltage (I/V) values), and outputs a predicted SoP.

In the key-off use-case, a SoP mapping is generated offline and so there is no need for measurables at the time of generating the mapping (except maybe EIS to correct for ageing factors, as shown above); however, even in the key-off use case, it is implicitly assumed that the SoP information will be eventually used for key-on purposes.

Referring to FIG. 15, a key-on use case 1500 is shown, in accordance with an exemplary aspect. The key-on use case 1500 involves a SoP model 1510 and a state tracker 1520. The SoP model 1510 and the state tracker 1520 both input measurable inputs (EIS, V, I, time (T), SoC, state of health (SoH), and so forth). The SoP model 1510 further inputs predicted battery state output from the state tracker 1520 and system limitations (e.g., maximum/minimum current/voltage (I/V) values), and outputs a predicted SoP.

In the key-on use case, battery state is tracked with a state tracker. In this case, more measurables, as well as system limitations, are provided to the model. Battery state, which affects SoP at a given time, is tracked over time. It will be recognized that SoP is relevant to both discharging and fast charging the battery.

It will be recognized that the proposed model provides battery module-level info, while SoP is a battery pack-level metric; therefore, the individual module-level SoP measurements must be combined appropriately to produce a pack-level SoP.

The following are SoP estimation approaches for key-off and key-on use cases. For the key-off use case, a regression model approach includes training a baseline regression model when at rest (offline) and generating SoP prediction by evaluating the regression function given predicted observable quantities and battery state. An ECM approach includes fitting an ECM to EIS measurements when at rest and generating SoP prediction by evaluating the ECM given predicted observable quantities and battery state.

For the key-on use case, a regression model approach includes training a baseline regression model when at rest (offline) and evaluating real-time SoP by evaluating the regression function given observable quantities. An ECM with Kalman Filter (KF) tracking approach includes fitting an ECM to EIS measurements when at rest (offline), using KF to track battery state, and evaluating a prediction based on the ECM (with constraints) to infer real-time SoP.

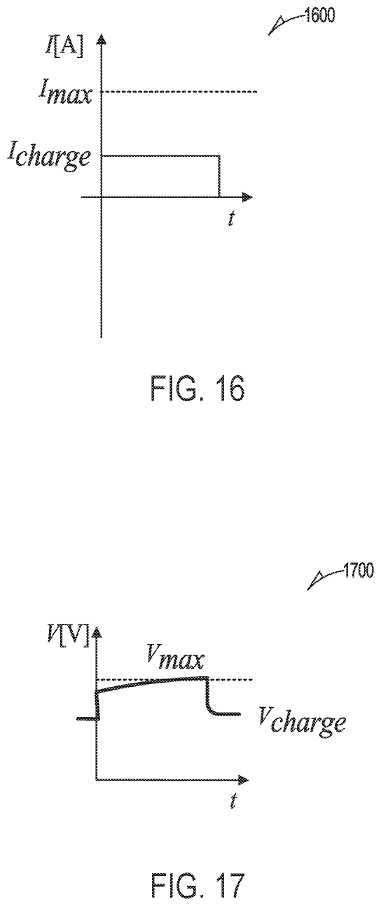

Referring back to FIG. 2 and further to FIGS. 16-17, the use of ECMs to perform SoP estimation is shown, in accordance with an exemplary aspect.

FIG. 2 as described above relates to battery ECM 200 used by the present disclosure in one exemplary aspect. Other battery ECMs can also be used while maintaining the spirit of the present disclosure such as that shown in FIG. 5 and others as described herein and as readily envisioned by one of ordinary skill in the art given the teachings of the present disclosure provided herein.

FIG. 16 shows a plot 1600 of current versus time for the battery ECM 200 of FIG. 2. In particular, time is represented in the x-axis, and current (including I_{charge} and Iₘₐₓ) is represented in the y-axis.

FIG. 17 shows a plot 1700 of voltage versus time for time for the battery ECM 200 of FIG. 2. In particular, time is represented in the x-axis, and voltage (including V_{charge} and Vₘₐₓ) is represented in the y-axis. V_{charge}(Δt)=Vₘₐₓ

First, the battery is modeled with R section 210 and RC section 220 and a voltage source V_{OCV} 230 if the ECM 200 of FIG. 2 is used. Alternatively, another model or representation can be used such as, but not limited to the ECM 500 of FIG. 5. The model is fit to the data taking into account parameter variations with temperature, SoC, and age. The parameterization of the model can be in the form of a look-up-table or regression function. Voltage response to a current step of desired duration (e.g., 10 secs, 60 secs, etc.) is calculated from an impedance spectrum that is determined at many frequencies and that can be used to fit models characterizing the electrochemical properties of the cell. The parameterization can be performed in closed-form or via sequential inference with a KF algorithm. For increased accuracy, ECM parameters can be adapted (closed-form approximations or on-line system identification in a KF framework). Constraints are set on current, SoC, voltage, etc., to find max current; this gives P=I*V.

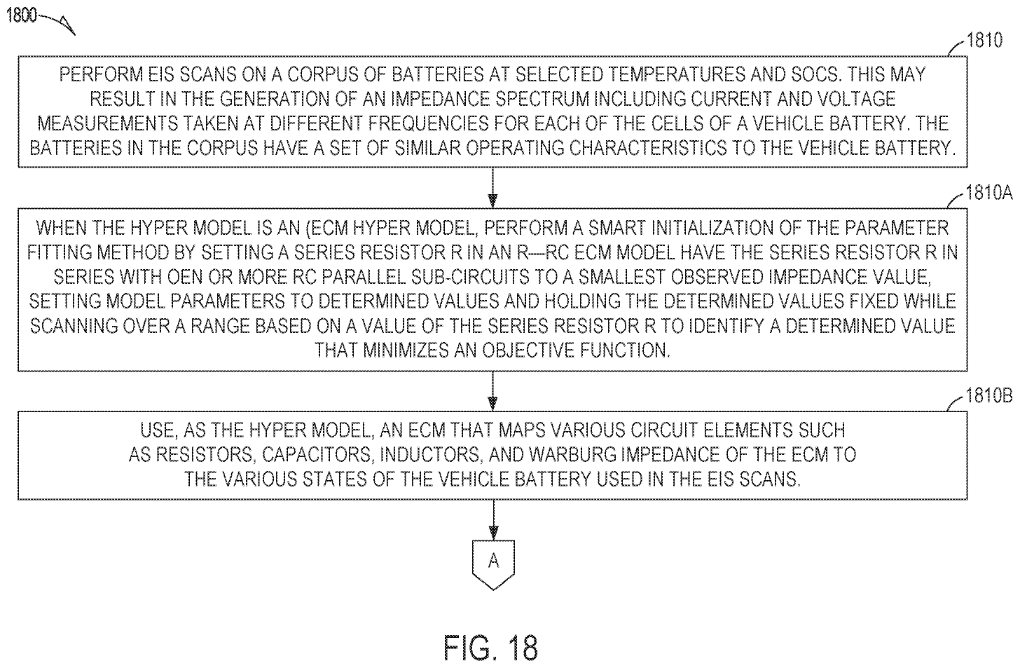

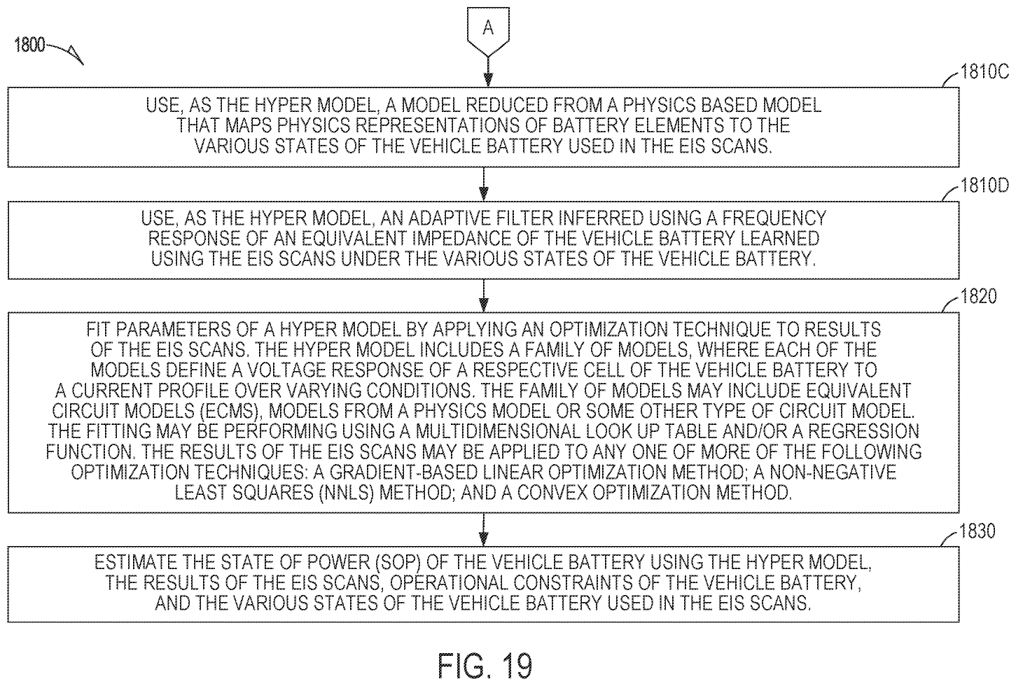

Referring to FIGS. 18-19, a method 1800 for offline pretraining of hyper model parameters is shown, in accordance with an exemplary aspect.

At step 1810, perform EIS scans on a corpus of batteries at selected temperatures and SoCs. This may result in the generation of an impedance spectrum including current and voltage measurements taken at different frequencies for each of the cells of a vehicle battery. The batteries in the corpus have a set of similar operating characteristics to the vehicle battery. The corpus of batteries having a set of similar operating characteristics to the vehicle battery refers to batteries having comparable battery chemistry, form factor, battery capacity, and operating conditions.

In an aspect, step 1810 may include one or more of step 1810A through 1810D.

Step 1810A includes, when the hyper model is an equivalent circuit model (ECM) hyper model, performing a smart initialization of the parameter fitting method by setting a series resistor R in an R-RC ECM model have the series resistor R in series with one or more RC parallel sub-circuits to a smallest observed impedance value, setting model parameters to determined values and holding the determined values fixed while scanning over a range based on a value of the series resistor R to identify a determined value that minimizes an objective function.

At step 1810B use, as the hyper model, an ECM that maps various circuit elements such as resistors, capacitors, inductors, and Warburg impedance of the ECM to the various states of the vehicle battery used in the EIS scans.

At step 1810C use, as the hyper model, a model reduced from a physics based model that maps physics representations of battery elements to the various states of the vehicle battery used in the EIS scans.

At step 1810D, use, as the hyper model, an adaptive filter inferred using a frequency response of an equivalent impedance of the vehicle battery learned using the EIS scans under the various states of the vehicle battery. In an aspect, the various states of the battery can include at least some of different temperature ranges of the battery, different states of charge (SoCs) of the battery, age of the battery, and a nature of a current load the battery is subjected to.

At step 1820, fit parameters of a hyper model by applying an optimization technique to results of the EIS scans. The hyper model includes a family of models, where each of the models define a voltage response of a respective cell of the vehicle battery to a current profile over varying conditions. The family of models may include equivalent circuit models (ECMs), models from a physics model or some other type of battery model. The fitting may be performing using a multidimensional look up table and/or a regression function. The results of the EIS scans may be applied to any one of more of the following optimization techniques: a gradient-based linear optimization method; a non-negative least squares (NNLS) method; and a convex optimization method.

At 1830, estimate the state of power (SoP) of the vehicle battery using the hyper model, the results of the EIS scans, operational constraints of the vehicle battery, and the various states of the vehicle battery used in the EIS scans.

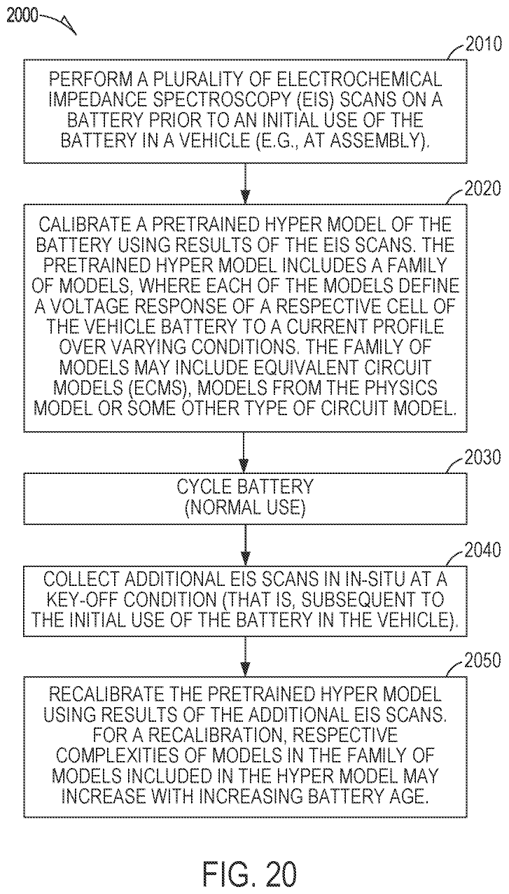

Referring to FIG. 20, a method 2000 for calibration and recalibration of a new cell is shown, in accordance with an exemplary aspect.

At step 2010, perform a plurality of electrochemical impedance spectroscopy (EIS) scans on a battery prior to an initial use of the battery in a vehicle (e.g., at assembly). This may result in the generation of an impedance spectrum including current and voltage measurements taken at different frequencies for each of the cells of the battery.

At step 2020, calibrate a pretrained hyper model of the battery using results of the EIS scans. The pretrained hyper model includes a family of models, where each of the models define a voltage response of a respective cell of the vehicle battery to a current profile over varying conditions. The family of models may include equivalent circuit models (ECMs), models from a physics model or some other type of battery model.

At step 2030, cycle the battery (normal use).

At step 2040, collect additional EIS scans in in-situ at a key-off condition (that is, subsequent to the initial use of the battery in the vehicle).

At step 2050, recalibrate the pretrained hyper model using results of the additional EIS scans. In an aspect, for a recalibration, respective complexities of models in the family of models included in the hyper model may increase with increasing battery age. In this way, the individual differences between each of the cells forming a battery can be accounted for and their respective aging and corresponding affects can be considered.

It will be noted that EIS scans can also be collected during in-use (i.e., key-on) rather than key-off in accordance with certain aspects.

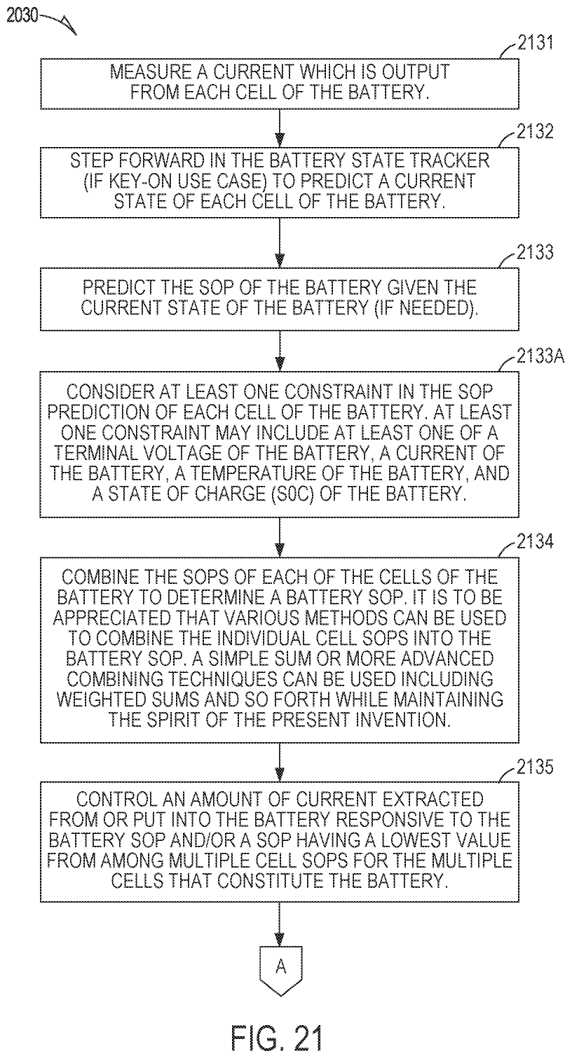

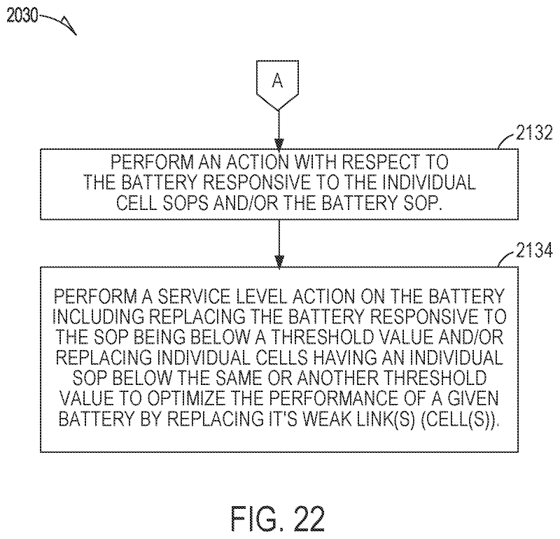

Referring to FIGS. 21-22, step 2030 of method 2000 of FIG. 20 is further shown, in accordance with an exemplary aspect.

At step 2131, measure a current which is output from each cell of the battery.

At step 2132, step forward in the battery state tracker (if key-on use case) to predict a current state of each cell of the battery.

At step 2133, predict the SoP of each cell of the battery responsive to the current state of each cell of the battery.

In an aspect, step 2133 can include step 2133A.

At step 2133A, consider at least one constraint in the SoP prediction of each cell of the battery. In an aspect, at least one constraint may include at least one of a terminal voltage of the battery, a current of the battery, a temperature of the battery, and a state of charge (SoC) of the battery.

At step 2134, combine the SoPs of each of the cells of the battery to determine a battery SoP. It is to be appreciated that various methods can be used to combine the individual cell SoPs into a battery SoP. A simple sum or more advanced combining techniques can be used including weighted sums and so forth while maintaining the spirit of the present disclosure.

At step 2135, perform an action with respect to the battery responsive to the individual cell SoPs and/or the battery SoP.

In an aspect, step 2135 can include one or more of steps 2035A and 2035B.

At step 2135A, control an amount of current extracted from or put into the battery responsive to the battery SoP and/or a SoP having a lowest value from among multiple cell SoPs for the multiple cells that constitute the battery.

At step 2135B, perform a service level action on the battery including replacing the battery responsive to the SoP being below a threshold value and/or replacing individual cells having an individual SoP below the same or another threshold value to optimize the performance of a given battery by replacing it's weak link(s) (cell(s)).

A further description of model fitting will now be given, in accordance with an exemplary aspect.

To fit this model to impedance measurements Zn at multiple frequencies, an objective function is defined as follows:

$$f = \frac{1}{2 N} {\sum }_{n} {\vert {e}_{n} \vert}^{2} \qquad ( 5 )$$

$$= \frac{1}{2 N} {\sum }_{n} {e}_{n , re}^{2} + {e}_{n , im}^{2} \qquad ( 6 )$$

$$= \frac{1}{2 N} {\sum }_{n} {( {Z}_{n , re} - {\hat{Z}}_{re} )}^{2} + {( {Z}_{n , im} - {\hat{Z}}_{im} )}^{2} \qquad ( 7 )$$

where eₙ=Zₙ-\hat{Z}(ω) is the complex-valued error of the fit and re and im subscripts denote real and imaginary parts. Its derivatives with respect to the (real-valued) model parameters are as follows:

$$\frac{\partial f}{\partial θ} = \frac{1}{N} {\sum }_{n} {e}_{n , re} \cdot ( - \frac{\partial {Z}_{re}}{\partial θ} ) + {e}_{n , im} \cdot ( - \frac{\partial {Z}_{im}}{\partial θ} ) \qquad ( 8 )$$

To simplify the derivations, the following shorthand notation is used:

$${T}_{i} = {R}_{i} {C}_{i} \qquad ( 9 )$$

$${δ}_{i} = ω {T}_{i} \qquad ( 10 )$$

$${∅}_{i} = 1 + {δ}_{i}^{2} \qquad ( 11 )$$

$${γ}_{i} = 1 - {δ}_{i}^{2} \qquad ( 12 )$$

The individual partial derivatives of the EIS model with respect to each parameter is as follows:

$$\frac{\partial \hat{Z}}{\partial {R}_{0}} = 1 \qquad ( 13 )$$

$$∀ i > 0 \frac{\partial \hat{Z}}{\partial {R}_{i}} = \frac{1}{{∅}_{i}^{2}} ( {γ}_{i} - j 2 {δ}_{i} ) \qquad ( 14 )$$

$$∀ i > 0 \frac{\partial \hat{Z}}{\partial {C}_{i}} = - \frac{ω {R}_{i}^{2}}{{∅}_{i}^{2}} ( 2 {δ}_{i} + j 2 {γ}_{i} ) \qquad ( 15 )$$

The impedance model formula can also be abbreviated as follows:

$$Z = {R}_{0} + {\sum }_{i} \frac{{R}_{i}}{1 + j {δ}_{i}} \qquad ( 16 )$$

$$= [ {R}_{0} + {\sum }_{i} \frac{{R}_{i}}{{∅}_{i}} ] + j [ - {\sum }_{i} \frac{{R}_{1} {δ}_{i}}{{∅}_{i}} ] \qquad ( 17 )$$

Given these formulas for the error and its derivatives, a non-linear optimization technique can be applied to tune the parameters to a dataset. It has to be ensured that the parameters remain non-negative.

A description will now be given regarding log-scaled parameters, in accordance with an exemplary aspect.

It is more natural to adjust the model parameters on a logarithmic scale, which is as simple as defining θ=e^{θ̅} for logarithmic-scale parameter counterparts θ̅. This also has the added benefit of ensuring non-negativity. Conveniently, ∂/∂θ̅=θ, so applying the chain rules gives:

$$\frac{\partial \hat{Z}}{\partial {R}_{0}} = \frac{\partial \hat{Z}}{\partial {R}_{0}} \cdot \frac{\partial {R}_{0}}{\partial {\overline{R}}_{0}} = {R}_{0} \frac{\partial \hat{Z}}{\partial {R}_{0}} \qquad ( 18 )$$

$$∀ i > 0 \frac{\partial \hat{Z}}{\partial {R}_{i}} = - \frac{\partial \hat{Z}}{\partial {R}_{i}} \cdot \frac{\partial {R}_{0}}{\partial {R}_{i}} = {R}_{i} \frac{\partial \hat{Z}}{\partial {R}_{i}} \qquad ( 19 )$$

$$∀ i > 0 \frac{\partial \hat{Z}}{\partial {C}_{i}} = - \frac{\partial \hat{Z}}{\partial {C}_{i}} \cdot \frac{\partial {C}_{i}}{\partial {C}_{i}} = {C}_{i} \frac{\partial \hat{Z}}{\partial {C}_{i}} \qquad ( 20 )$$

A description will now be given regarding R-τ parameterization, in accordance with an exemplary aspect.

The model can be re-parameterized via τᵢ=RᵢCᵢ. In this case, the impedance model is as follows:

$$Z ( ω ) = [ {R}_{0} + {\sum }_{i} \frac{{R}_{i}}{1 + {ω}^{2} {τ}_{i}^{2}} ] + j [ - {\sum }_{i} \frac{ω {R}_{i} {τ}_{i}}{1 + {ω}^{2} {τ}_{i}^{2}} ] \qquad ( 21 )$$

and its derivatives are as follows:

$$\frac{\partial \hat{Z}}{\partial {R}_{0}} = 1 \qquad ( 22 )$$

$$∀ i > 0 \frac{\partial \hat{Z}}{\partial {R}_{i}} = \frac{1}{{∅}_{i}} ( 1 - j {δ}_{i} ) \qquad ( 23 )$$

$$∀ i > 0 \frac{\partial \hat{Z}}{\partial {τ}_{i}} = - \frac{ω {R}_{i}}{{∅}_{i}^{2}} ( 2 {δ}_{i} + {γ}_{i} ) \qquad ( 24 )$$

A description will now be given regarding additional considerations, in accordance with an exemplary aspect.

A line search at each iteration ensures that the error is never increased. Also, well-known measures to improve convergence behavior can be implemented like adaptive step size and momentum.

An initialization can be used. The initialization is particularly applicable to R-RC-type models in order to get in the vicinity of an optimum. R₀ is set to the smallest observed impedance value. Then the r parameters are set to a reasonable intermediate value (empirically/visually determined). Holding those, fixed, a scan is performed over a range of Rᵢi>0 values with all of them held equal to each other to find the one that minimizes the objective. Finally, the Rᵢ and τᵢ (i>0) values are deterministically spread over a small range around the initial values to avoid ambiguities. This seems to work quite well in practice. This results in a smart initialization of the R-RC type models.

A further description will now be given of the hyper model, in accordance with an exemplary aspect.

In practice, a model of impedance is wanted that generalizes to many temperatures and SoCs because it is known that the model parameters vary quite a lot with respect to these states. If an RC model is fit with a standardized, deterministic initialization procedure, a permutation problem can be avoided between the RC pairs that could severely complicate the generalization procedure. Once all the individual models are fit, a 3^{rd}-order polynomial can be fit via least-squares regression to each parameter.

A description will now be given regarding time-domain voltage prediction, in accordance with an exemplary aspect.

Given an ECM, the time-domain voltage response to a current input can be expressed. For an R-RC-type model, the following equations from voltage and current laws can be used:

$${V}_{term} ( t ) = {V}_{OCV} ( t ) - {R}_{0} i ( t ) - {\sum }_{j} {V}_{{C}_{j}} ( t ) \qquad ( 25 )$$

$$i ( t ) = \frac{1}{{R}_{j}} {V}_{{C}_{j}} ( t ) + {C}_{j} {\dot{V}}_{{C}_{j}} ( t ) \qquad ( 26 )$$

The latter can be re-written as follows:

$${\dot{V}}_{{C}_{j}} ( t ) = - \frac{1}{{τ}_{j}} {V}_{{C}_{j}} ( t ) + \frac{{R}_{j}}{{τ}_{j}} i ( t ) \qquad ( 27 )$$

Thus, only the voltages over the RC pairs need to be solved to be able to predict Vₜₑᵣₘ(t) and it is also desired that those voltage functions be discretized.

A description will now be given regarding Euler approximations, in accordance with an exemplary aspect.

Applying the forward Euler approximation, the following is obtained:

$${V}_{{C}_{j}} ( t + Δ t ) = {V}_{{C}_{j}} ( t ) + Δ t {\dot{V}}_{{C}_{j}} ( t ) \qquad ( 28 )$$

$$= ( 1 - \frac{{Δ}_{t}}{{τ}_{j}} ) {V}_{{C}_{j}} ( t ) + \frac{{Δ}_{t}}{{τ}_{j}} {R}_{j} i ( t ) \qquad ( 29 )$$

$${V}_{{C}_{j}} [ n + 1 ] = ( 1 - \frac{{Δ}_{t}}{{τ}_{j}} ) {V}_{{C}_{j}} ( n ) + \frac{{Δ}_{t}}{{τ}_{j}} {R}_{j} i ( n ) \qquad ( 30 )$$

and applying backward Euler, the following is obtained:

$${V}_{{C}_{j}} ( t + Δ t ) = {V}_{{C}_{j}} ( t ) + Δ t {\dot{V}}_{{C}_{j}} ( t + Δ t ) \qquad ( 31 )$$

$$= ( \frac{{τ}_{j}}{{τ}_{j} + Δ t} ) {V}_{{C}_{j}} ( t ) + ( \frac{Δ t}{{τ}_{j} + Δ t} ) {R}_{j} i ( t + Δ t ) \qquad ( 32 )$$

$${V}_{{C}_{j}} [ n + 1 ] = ( \frac{{τ}_{j}}{{τ}_{j} + Δ t} ) {V}_{{C}_{j}} ( n ) + ( \frac{Δ t}{{τ}_{j} + Δ t} ) {R}_{j} i [ n + 1 ] \qquad ( 33 )$$

Both of these solutions describe a convex combination of the voltage Vcⱼ[n] and the voltage Rⱼi[n] but differ in the mixing coefficients and whether to use the present or previous step's current. Difference equations of this form, i.e.:

$$y [ n ] = a y [ n - 1 ] + ( 1 - a ) u [ n ] \qquad ( 34 )$$

have the following closed-form solution in the time-domain for constant u[n]:

$$∀ n \geq {n}_{0} y [ n ] = ( y [ {n}_{0} ] - u ) {a}^{n - {n}_{0}} + u \qquad ( 35 )$$

This equation may be used to predict what the voltage will be at any time in the future given a constant current and initial voltage condition.

A description will now be given regarding closed-form voltage prediction for the discretized model, in accordance with an exemplary aspect.

Substituting the solution for the RC pair voltage from the backward Euler approximation into the terminal voltage formula, the following is obtained:

$${V}_{term} [ n ] = {V}_{O C V} [ n ] - {R}_{0} {i}^{*} - {\sum }_{j} {V}_{{C}_{j}} ( {V}_{{C}_{j}} [ 0 ] - {R}_{j} {i}^{*} ) {c}_{j}^{n} + {R}_{j} {i}^{*} \qquad ( 36 )$$

for a constant current i* using n₀=0, u=Rⱼi*, and the shorthand:

$${C}_{j} = \frac{{τ}_{j}}{{τ}_{j} + Δ t} \qquad ( 37 )$$

There are two issues with this expression:

SoC dependence: It does not take into account the dependence of the ECM parameters on SoC, which could change non-negligibly during the prediction horizon depending on the current magnitude. This is addressed by an SoC-dependent ECM, and as Cⱼ is a constant, this equation does not work for varying SoCs.

Initial conditions: Initial values have to be provided for the voltages V_{C}_{ⱼ}[0] across each of the RC pairs. This is handled by an appropriate tracking scheme.

A description will now be given regarding explicit solution to the continuous-time model, in accordance with an exemplary aspect.

Since the full system model is completely decoupled, and each ODE is linear and of first order, this system can be solved explicitly to get expressions for voltages V_{C}_{ⱼ}. Namely, from (27), the following is directly obtained:

$${V}_{{C}_{j}} ( t ) = {V}_{{C}_{j}} ( {t}_{0} ) e - \frac{t - {t}_{0}}{{τ}_{j}} + \frac{{R}_{j}}{{τ}_{j}} {\int }_{{t}_{0}}^{t} i ( ξ ) e - \frac{t - ξ}{{τ}_{j}} d ξ , t > {t}_{0} , ∀ j . \qquad ( 38 )$$

Assuming that i(t)=i₀ is constant in the interval of interest, the following is obtained:

$${V}_{{C}_{j}} ( t ) = {V}_{{C}_{j}} ( {t}_{0} ) e - \frac{t - {t}_{0}}{{τ}_{j}} + {R}_{j} {i}_{0} ( e - \frac{{t}_{0}}{{τ}_{j}} - e - \frac{t}{{τ}_{j}} ) . \qquad ( 39 )$$

Similarly, if the system parameters Rⱼ and iⱼ are time-varying (e.g., if they depend on SOC or cell temperature), the explicit solution for V_{C}_{ⱼ} can be written as follows:

$${V}_{{C}_{j}} ( t ) = {V}_{{C}_{j}} ( {t}_{0} ) {e}^{- A ( t ) + A ( {t}_{0} )} + {\int }_{{t}_{0}}^{t} \frac{{R}_{j} ( ξ )}{{τ}_{j} ( ξ )} i ( ξ ) {e}^{- A ( t ) + A ( ξ )} d ξ , t > {t}_{0} , ∀ j . \qquad ( 40 )$$

Where ϕ=ϕ(t) is the antiderivative of 1/τⱼ(t)′, that is,

$$ϕ ( t ) = \int \frac{1}{{τ}_{j} ( t )} d t .$$

If model parameters Rⱼ(t) and Cⱼ(t)=Rⱼ(t)/τⱼ(t) can be explicitly described as functions of time then the above integrals can be either explicitly solved, or numerically integrated. For example, given starting SOC and cell temperature, it should be possible to approximate model parameters with low order polynomials (e.g., linear or quadratic) over a small time-window under consideration.

For example, Rⱼ(t) and τⱼ(t) may be modeled as:

$${R}_{j} ( t ) = {a}_{j} t + {b}_{j} , {τ}_{j} = {a}_{j} t + {β}_{j} for t ∈ [ {t}_{0} , {t}_{0} + ϵ ] and all j , \qquad ( 1 )$$

$${R}_{j} ( t ) = {a}_{j} {t}^{2} + {b}_{j} , {τ}_{j} = {a}_{j} t + {β}_{j} for t ∈ [ {t}_{0} , {t}_{0} + ε ] and all j , \qquad ( 2 )$$

where ∈ is some small positive constant.

A description will now be given regarding prediction based on the explicit solution to a continuous-time state-space model, in accordance with an exemplary aspect.

While the battery is in use, the SoP algorithm has to be capable of providing, at any moment in time, an estimate of the maximal power that can be put into or drawn from the battery in some pre-defined small time window. Therefore, in order to accurately estimate P(t) it is necessary to have an accurate prediction of the cell terminal voltage waveform Vₜₑᵣₘ(⋅) over the time-horizon [t, t+Tₚ]. The battery performance can be evaluated by the discharge or charge energy E(t) while maintaining an SoP. The energy is expressed as follows:

$$E ( t ) = {\int }_{t}^{t + {T}_{p}} P ( τ ) d τ \qquad ( 41 )$$

$$E ( t ) = {\int }_{t}^{t + {T}_{p}} {V}_{term} ( τ ) \cdot i ( τ ) d τ \qquad ( 42 )$$

The energy can be approximated using the composite Simpson's rule Riemann sum shown below

$$E ( t ) \approx {\sum }_{j = 1}^{N / 2} \frac{Δ {τ}_{k}}{3} [ \text{} {V}_{term} ( {τ}_{2 j - 2} ) \cdot i ( {τ}_{2 j - 2} ) + 4 {V}_{term} ( {τ}_{2 j - 1} ) \cdot i ( {τ}_{2 j - 1} ) + {V}_{term} ( {τ}_{2 j} ) \cdot i ( {τ}_{2 j} ) ] \qquad ( 43 )$$

where j=0,1, . . . , N−1, N for N even subintervals and the j-th time step is

$${Δ}_{{τ}_{k}} = {τ}_{k + 1} - {τ}_{k} [ t , t + {T}_{p} ] \qquad ( 44 )$$

A description will now be given regarding a conservative SoP Estimation, in accordance with an exemplary aspect.

Applying a constant discharge or charge at iₘₐₓ does not result in constant power because of varying battery voltage. A constant power discharge or charge using the average power as the SoP might not be possible since voltages near V_{term,min} will require higher currents than iₘₐₓ which can be constrained to the manufacturers' limits. The peak power is described in (45) which is an underestimate of the maximum power.

$$P = {V}_{term , min} {i}_{max} \qquad ( 45 )$$

A constant current pulse would imply an infinite current change rate at the beginning of the pulse. This can be considered the worst-case scenario and is used because of the following reasons:
Current can be easily controlled by power electronics.
Voltage change during constant current pulses are negligible.

A description will now be given regarding a Newton-Raphson Method to find iₘₐₓ for the Conservative SoP Estimate, in accordance with an exemplary aspect.

The max cell current results in the maximal power that can be drawn from the battery and is constrained by the minimum terminal voltage, V_{term,min}. The problem statement becomes:

Problem: Solve for iₘₐₓ=i* given Vₜₑᵣₘ(i,t+Tₚ) such that ƒ(i*)=Vₜₑᵣₘ(i*,t+Tₚ)−V_{term,min}=0 over the time-horizon t[t+Tₚ].

The Newton-Raphson method is a powerful technique to solve root-finding problems numerically using linear approximations. With 2 initial guesses for iₘₐₓ being i₀ and i₁ the secant method is used to approximate the derivative and follows (46) until the tolerance for termination is satisfied for [iₙ−iₙ₋₁].

$${i}_{n} = {i}_{n - 1} - f ( {i}_{n - 1} ) \frac{{i}_{n - 1} - {i}_{n - 2}}{f ( {i}_{n - 1} ) - f ( {i}_{n - 2} )} \qquad ( 46 )$$

The Vₜₑᵣₘ(i, t+Tₚ) function returns the final terminal voltage at t+Tₚ. This functions uses the state space model from (56) without observations with constant current i such that it is predicting the state for time T_{P}.

The main issues with using this method include:
Bad initial guesses where the function doesn't converge;
Sub-quadratic convergence rate; and
Solutions with noisy voltages that can reach below V_{term,min} in previous time steps t+Tₚ.

Possible improvements:
Use Brent's Method that combines the bisection method, the secant method and inverse quadratic interpolation to bound current within an interval;
Log updates to restrict the current to be non-negative; and
Use a termination condition for ƒ(iₙ) instead of iₙ for steep slopes

A description will now be given of a constant power method to find Pₘₐₓ for SoP, in accordance with an exemplary aspect.

The max constant power results in more energy output than the conservative estimate for SoP. The maximum constant power discharge that results in the battery specified minimum terminal voltage at t+Tₚ is found numerically utilizing Powell's method. Batteries have maximum current discharge and charge pulses that need to be considered to restrict the current profile. This is accomplished by solving for the current at t+Tₚ that is equal to the maximum discharge pulse current up to Tₚ if the current reaches higher than the specification to reach the cut-off voltage. However, searching for this current profile that results in a constant power discharge is required with changing voltage, temperature, and SoC.

A description will now be given regarding a constant power simulation, in accordance with an exemplary aspect.

To find the max constant power discharge or charge a current profile needs to be solved to compensate for the changing voltage of the model. The current at each time step is computed numerically using Powell's methods. With shorthand form

$${C}_{j} = \frac{{τ}_{j}}{{τ}_{j} + Δ t} \qquad ( 47 )$$

The current profile can be derived using 26 and 33 at the next time step n.

$$p [ n ] = {V}_{term} [ n ] i [ n ] \qquad ( 48 )$$

$$p [ n ] = ( {V}_{OCV} [ n ] - {R}_{0} i [ n ] - {\sum }_{j} {V}_{{C}_{j}} [ n ] ) i [ n ] \qquad ( 49 )$$

$$p [ n ] = ( {V}_{OCV} [ n ] - {R}_{0} i [ n ] - {\sum }_{j} {C}_{j} {V}_{{C}_{j}} [ n - 1 ] + ( 1 - {C}_{j} ) {R}_{j} i [ n ] ) i [ n ] \qquad ( 50 )$$

$$p [ n ] = ( {V}_{OCV} [ n ] - {\sum }_{j} {C}_{j} {V}_{{C}_{j}} [ n - 1 ] ) i [ n ] - ( {R}_{0} + {\sum }_{j} ( 1 - {C}_{j} ) {R}_{j} ) {i [ n ]}^{2} \qquad ( 51 )$$

V_{OCV} is dependent on SoC and temperature. To solve for the current i[n] that results in a constant power discharge, V_{OCV} [n] can be expressed in terms of i[n] and V_{OCV} [n−1] using the OCV-SoC inverse function relationship. However, since the OCV-SOC function is not defined yet an approximation of V_{OCV}[n]≈V_{OCV}[n−1] can be made with a small enough time step since the SoC change is insignificant. The current i[n] can be solved directly using (51) with the quadratic equation with a negative sign for positive overall cell voltage.

$$p [ n ] \approx ( {V}_{OCV} [ n - 1 ] - {\sum }_{j} {C}_{j} {V}_{{C}_{j}} [ n - 1 ] ) i [ n ] - ( {R}_{0} + {\sum }_{j} ( 1 - {C}_{j} ) {R}_{j} ) {i [ n ]}^{2} \qquad ( 52 )$$

$$i [ n ] \approx \frac{( {V}_{O C V} [ n - 1 ] - {\sum }_{j} {C}_{j} {V}_{{C}_{j}} [ n - 1 ] )}{2 ( {R}_{0} + {\sum }_{j} ( 1 - {C}_{j} ) {R}_{j} )} - \frac{\sqrt{{( {\sum }_{j} {C}_{j} {V}_{{C}_{j}} n - 1 - {V}_{O C V} [ n - 1 ] )}^{2} - 4 ( {R}_{0} + {\sum }_{j} ( 1 - {C}_{j} ) {R}_{j} ) p [ n ]}}{2 ( {R}_{0} + {\sum }_{j} ( 1 - {C}_{j} ) {R}_{j} )} \qquad ( 53 )$$

Results show that with a small enough time step (˜100 ms) the desired power matches very closely to the calculated power. This function could be useful for more efficient computing of the SoP on an embedded system.

A description will now be given regarding tracking, in accordance with an exemplary aspect. The description will address a state space model and EKF approximation.

A description of a state space model will now be given, in accordance with an exemplary aspect.

The full state-space model corresponding to the backward Euler discretization for 2 RC pairs has state transition equation:

$$[ \begin{matrix}s [ n ] \\ {V}_{{C}_{1}} [ n ] \\ {V}_{{C}_{2}} [ n ]\end{matrix} ] = [ \begin{matrix}1 & 0 & 0 \\ 0 & {a}_{1} & 0 \\ 0 & 0 & {a}_{2}\end{matrix} ] [ \begin{matrix}s [ n - 1 ] \\ {V}_{{C}_{1}} [ n - 1 ] \\ {V}_{{C}_{2}} [ n - 1 ]\end{matrix} ] + [ \begin{matrix}- Δ t / cap \\ ( 1 - {a}_{1} ) {R}_{1} \\ ( 1 - {a}_{2} ) {R}_{2}\end{matrix} ] i [ n ] \qquad ( 54 )$$

which can be abbreviate to the following:

$$x [ n ] = A x [ n - 1 ] + b i [ n ] \qquad ( 55 )$$

for J×1 state vector x, J×J state transition matrix A, and J×1 control input vector b. The following shorthand is used:

$${a}_{i} = \frac{{τ}_{j}}{{τ}_{j} + Δ t} . \qquad ( 56 )$$

The measurement equation is as follows:

$${V}_{term} [ n ] = {V}_{O C V} [ n ] ( [ 100 ] x [ n ] ) - [ 011 ] x [ n ] - {R}_{0} i [ n ] \qquad ( 56 )$$

which is abbreviated to the following:

$$y [ n ] = f ( x [ n ] ) + d i [ n ] \qquad ( 57 )$$

for non-linear function ƒ(⋅) and control input scalar d. The dependence of SoC (i.e., s[n]) on the OCV at time step n has been included. The OCV-SoC function ƒ(⋅) can be estimated empirically and approximated with a 9^{th}-order polynomial, for example, to allow for deriving an EKF approximation.

The presence of the control input i[n] translates to very simple adjustments to the resulting Kalman filter's predict and correct steps.

A description will now be given of an EKF approximation, in accordance with an exemplary aspect.

The Extended Kalman Filter (EKF) is a useful and simple approach for approximating non-linearities in a dynamical model. Given the state space model defined above, the following generative model is assumed:

$${x}_{n} = {A}_{n} {x}_{n - 1} + {b}_{n} {i}_{n} + {∈}_{n} \qquad ( 58 )$$

$${Y}_{n} = f {x}_{n} + {d}_{n} {i}_{n} + {δ}_{n} \qquad ( 59 )$$

with noise processes:

$$∈ ∼ N ( 0 , Q ) \qquad ( 60 )$$

$$δ ∼ N ( 0 , R ) \qquad ( 61 )$$

The corresponding EKF equations are as follows and as shown in FIG. 13:

### Predict

$${\hat{x}}_{n \vert n - 1} = {A}_{n} {\hat{x}}_{n - 1} + {b}_{n} {U}_{n} \qquad ( 62 )$$

$${\hat{\sum }}_{n \vert n - 1} = {A}_{n} {\hat{\sum }}_{n - 1} {A}_{n}^{T} + Q \qquad ( 63 )$$

### Linearize

$$c = {[ \frac{\partial f ( x )}{\partial x} ]}^{T} {\vert}_{x = {x}_{n \vert n - 1}} \qquad ( 64 )$$

### Correct

$${\hat{Y}}_{n} = f ( {\hat{x}}_{n \vert n - 1} ) + {d}_{n} {i}_{n} \qquad ( 65 )$$

$${r}_{n} = {Y}_{n} - {\hat{Y}}_{n} \qquad ( 66 )$$

$${S}_{n} = \overline{c} {\hat{\sum }}_{n \vert n - 1} {\overline{c}}^{T} + R \qquad ( 67 )$$

$${K}_{n} = {\hat{\sum }}_{n \vert n - 1} {\overline{c}}^{T} {S}_{n}^{- 1} \qquad ( 68 )$$

$${\hat{x}}_{n} = {\hat{x}}_{n \vert n - 1} + {K}_{n} {r}_{n} \qquad ( 69 )$$

$${\hat{\sum }}_{n} = ( I - {K}_{n} {\overline{c}}_{n} ) {\hat{\sum }}_{n \vert n - 1} \qquad ( 70 )$$

where use is made of the Jacobian c̅ of the state-dependent measurement function.

The system matrices are expressed as a function of step index because they depend on the ECM parameters, which themselves are functions of SoC and temperature. SoC is tracked in the model and temperature is provided externally, so it is assumed that the non-linearity introduced by that interdependence is negligible. The system matrices also depend on the step duration, which can vary over time.

When no measurements are available, the EKF will only perform the predict step. This allows it to continue “tracking” when measurements are not available.

### Additional Aspects

The present disclosure may additionally include one or more of the following aspects.

Aspect 1. A method for pretraining a hyper model configured for use in predicting a state of power (SoP) of a vehicle battery, the method comprising:
performing electrochemical impedance spectroscopy (EIS) scans on a plurality of batteries having a set of similar operating characteristics to the vehicle battery, the EIS scans performed across various states of the vehicle battery; and
fitting parameters of the hyper model by applying an optimization technique to results of the EIS scans, the hyper model comprising a family of models that each define a voltage response of a respective cell from among a plurality of cells of the vehicle battery to a current profile over the various states of the vehicle battery.

Aspect 2. The method according to aspect 1, further comprising estimating the state of power (SoP) of the vehicle battery using the hyper model, the results of the EIS scans, operational constraints of the vehicle battery, and the various states of the vehicle battery used in the EIS scans.

Aspect 3. The method according to aspect 1, wherein the various states of the vehicle battery include at least some of: different temperature ranges of the vehicle battery; different states of charge (SoCs) of the vehicle battery; age of the vehicle battery; and a nature of a current load the vehicle battery is subjected to.

Aspect 4. The method according to aspect 1, wherein the hyper model is an equivalent circuit model (ECM) that maps various circuit elements such as resistors, capacitors, inductors, and Warburg impedance of the ECM to the various states of the vehicle battery used in the EIS scans.

Aspect 5. The method according to aspect 1, wherein the hyper model is a model reduced from a physics based model that maps physics representations of battery elements to the various states of the vehicle battery used in the EIS scans.

Aspect 6. The method according to aspect 1, wherein the hyper model is an adaptive filter inferred using a frequency response of an equivalent impedance of the vehicle battery learned using the EIS scans under the various states of the vehicle battery.

Aspect 7. The method according to any of aspects 1-6, wherein the fitting is performed offline.

Aspect 8. The method according to any of aspects 1-7, wherein a multidimensional look up table is used to map the hyper model, an expected battery state, the results of the EIS scans, and battery system current and voltage limitations into a corresponding SoP value.

Aspect 9. The method according to aspect 1, wherein a mapping from the EIS scans, the various states of the vehicle battery, and operational constraints of the vehicle battery to the state of power (SoP) of the battery is performed using a regression function learned under the various states of the vehicle battery.

Aspect 10. The method according to aspect 1, wherein the results of the EIS scans are used to infer a hyper model using an optimization technique selected from the group consisting of a gradient-based linear optimization method, a non-negative least squares (NNLS) method, and a convex optimization method.

Aspect 11. The method according to aspect 1, wherein the hyper model is a family of equivalent circuit models (ECMs), and the method further comprises performing a smart initialization of a parameter fitting method by setting a series resistor R in an R-RC ECM model having the series resistor R in series with one or more RC parallel sub-circuits to a smallest observed impedance value, setting model parameters to determined values and holding the determined values fixed while scanning over a range based on a value of the series resistor R to identify a determined value that minimizes an objective function.

Aspect 12. A method for predicting a state of power (SoP) of a battery, the method comprising:
performing a plurality of electrochemical impedance spectroscopy (EIS) scans on the battery prior to an initial use of the battery in a vehicle;
calibrating a pretrained hyper model using results of the plurality of EIS scans, the hyper model comprising a family of models that each define a voltage response of a respective cell from among a plurality of cells of the battery to a current profile over various states of the batterys;
performing a plurality of additional EIS scans on the battery subsequent to the initial use of the battery in the vehicle;
recalibrating the pretrained hyper model using results of the plurality of additional EIS scans;
predicting the SoP of each of multiple cells of the vehicle battery responsive to a current battery state of each of the multiple cells;
combining the SoP of each of multiple cells into a battery SoP; and
controlling an amount of current extracted from or put into the battery responsive to a SoP value.

Aspect 13. The method according to aspect 12, wherein the plurality of additional EIS scans are periodically performed subsequent to the initial use of the battery in the vehicle.

Aspect 14. The method according to aspect 12, wherein the various states of the battery include at least some of different temperature ranges of the battery, different states of charge (SoCs) of the battery, age of the battery, and a nature of a current load the battery is subjected to.

Aspect 15. The method according to aspect 12, wherein the hyper model is an equivalent circuit model (ECM) that maps various circuit elements such as resistors, capacitors, inductors, and Warburg impedance of the ECM to the various states of the battery used in the EIS scans.

Aspect 16. The method according to aspect 12, wherein the hyper model is a model reduced from a physics based model that maps physics representations of battery elements to the various states of the battery used in the EIS scans.

Aspect 17. The method according to aspect 12, wherein the hyper model is an adaptive filter inferred using a frequency response of an equivalent impedance of the battery learned using the EIS scans under the various states of the battery used in the EIS scans.

Aspect 18. The method according to aspect 12, wherein the results of the EIS scans are used to infer a hyper model using an optimization technique selected from the group consisting of a gradient-based linear optimization method, a non-negative least squares (NNLS) method, and a convex optimization method.

Aspect 19. The method according to aspect 12, wherein the hyper model is a family of equivalent circuit models (ECMs), and the method further comprises performing a smart initialization of a parameter fitting method by setting a series resistor R in an R-RC ECM model having the series resistor R in series with one or more RC parallel sub-circuits to a smallest observed impedance value, setting model parameters to determined values and holding the determined values fixed while scanning over a range based on a value of the series resistor R to identify a determined value that minimizes an objective function.

Aspect 20. The method according to aspect 12, wherein the plurality of additional EIS scans is performed while the battery is in a key-on condition.

Aspect 21. The method according to aspects 12 or 20, further comprising, during a key-on condition of the battery:
measuring a current output from each of multiple cells of the battery; and
determining the current battery state of each of the multiple cells of the battery responsive to the current output from each of the multiple cells of the battery.

Aspect 22. The method according to aspect 12, further comprising predicting the SoP of at least one of the cells of the battery, wherein at least one constraint comprises at least one of a terminal voltage of the battery, a current of the battery, a temperature of the battery, and a state of charge (SoC) of the battery.

Aspect 23. The method according to aspect 12, wherein the plurality of additional EIS scans is performed while the battery is in a key-off condition to update the hyper model.

Aspect 24. The method according to aspect 12, wherein in a key-off condition, the battery SoP is estimated using a regression algorithm given EIS measurements and a current state of the battery.

Aspect 25. The method according to aspect 12, wherein the SoP comprises a maximum allowable static current that can be sustained for a given time period.

Aspect 26. The method according to aspect 25, wherein the maximum allowable static current comprises a level of current that does not cause a constraint violation.

Aspect 27. The method according to aspect 25, wherein the maximum allowable static current comprises a level of current that does not result in a temporary loss of capacity of more than a specified fraction over a given time period.

Aspect 28. The method according to aspect 12, wherein the SoP comprises a maximum allowable constant power that can be sustained for a given time period.

Aspect 29. The method according to aspect 20, further comprising tracking a battery state starting from a known initial condition responsive to measurable inputs comprising the results of the EIS scans.

Aspect 30. The method according to aspect 20, further comprising tracking a battery state including a terminal voltage of the battery using an Extended Kalman filter (EKF) technique that comprises predicting a battery state vector using a state space model and predicting the terminal voltage of the battery response over a desired period of time.

Aspect 31. The method according to aspect 30, wherein the EKF technique comprises forming battery system matrices expressed as a function of a step index that is dependent on parameters of the hyper model that, in turn, are dependent on the various states of the battery.

Aspect 32. The method according to aspect 20, further comprising estimating the battery state including a terminal voltage of the battery using a closed form solution to discrete approximations of a state space model and predicting the terminal voltage of the battery response over a desired period of time.

Aspect 33. The method according to aspect 20, further comprising generating a prediction for a current SoP of the battery responsive to a present prediction of the battery state, measurable inputs, and system limitations relating to current and voltage maximum and minimum values.

Aspect 34. The method according to aspect 33, wherein the battery state comprises a present battery current, a present terminal voltage, a present open circuit voltage (OCV), and a present impedance measurement obtained using EIS.

Aspect 35. The method according to aspect 12, wherein, for a recalibration, respective complexities of models in the family of models comprised in the hyper model increase with increasing battery cell age.

Aspect 36. The method according to aspect 12, wherein the SoP of the battery is equal to one of the SoPs of each of multiple cells.

Aspect 37. The method according to aspect 12, wherein the SoP value of a battery is equal to a lowest value from among the multiple cell SoPs for the multiple cells that constitute the battery.

Aspect 38. The method according to aspect 12, wherein the SoP value is equal to the battery SoP.

Aspect 39: A system for predicting a state of power (SoP) of a battery, the system comprising:
an electrochemical impedance spectroscopy (EIS) system for performing a plurality of EIS scans on the battery priorto an initial use of the battery in a vehicle, and a plurality of additional EIS scans on the battery in the vehicle;
a memory device for storing program code; and
a processing device operatively coupled to the EIS system and the memory device for running the program code to:
   calibrate a pretrained hyper model using results of the plurality of EIS scans, the pretrained hyper model comprising a family of models that each define a voltage response of a respective cell from among a plurality of cells of the battery to a current profile over various states of the battery;
   recalibrate the pretrained hyper model using results of the plurality of additional EIS scans;
   predict the SoP of each of multiple cells of the vehicle battery responsive to a current battery state of each of the multiple cells;
   combine the SoPs of each of multiple cells into a battery SoP; and
   control an amount of current extracted from or put into the battery responsive to at least one of the SoPs of each of multiple cells or the battery SoP.

Aspect 40. A system having one or more components configured to perform the function of any of aspects 13 to 38.

It should be noted that all of the specifications, dimensions, and relationships outlined herein (e.g., the number of elements, operations, steps, etc.) have only been offered for purposes of example and teaching only. Such information may be varied considerably without departing from the spirit of the present disclosure, or the scope of the appended claims. The specifications apply only to one non-limiting example and, accordingly, they should be construed as such. In the foregoing description, exemplary aspects have been described with reference to particular component arrangements. Various modifications and changes may be made to such aspects without departing from the scope of the appended claims. The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system may be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and may accommodate a large number of components, as well as more complicated/sophisticated arrangements and configurations. Accordingly, the examples provided should not limit the scope or inhibit the broad teachings of the electrical circuits as potentially applied to myriad other architectures.

It should also be noted that in this Specification, references to various features (e.g., elements, structures, modules, components, steps, operations, characteristics, etc.) included in “one aspect”, “exemplary aspect”, “an aspect”, “another aspect”, “some aspects”, “various aspects”, “other aspects”, “alternative aspect”, and the like are intended to mean that any such features are included in one or more aspects of the present disclosure, but may or may not necessarily be combined in the same aspects.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

It should also be noted that the functions related to circuit architectures illustrate only some of the possible circuit architecture functions that may be executed by, or within, systems illustrated in the FIGURES. Some of these operations may be deleted or removed where appropriate, or these operations may be modified or changed considerably without departing from the scope of the present disclosure. In addition, the timing of these operations maybe altered considerably. The preceding operational flows have been offered for purposes of example and discussion. Substantial flexibility is provided by aspects described herein in that any suitable arrangements, chronologies, configurations, and timing mechanisms may be provided without departing from the teachings of the present disclosure.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

Note that all optional features of the device and system described above may also be implemented with respect to the method or process described herein and specifics in the examples may be used anywhere in one or more aspects.

The “means for” in these instances (above) may include (but is not limited to) using any suitable component discussed herein, along with any suitable software, circuitry, hub, computer code, logic, algorithms, hardware, controller, interface, link, bus, communication pathway, etc.

Note that with the example provided above, as well as numerous other examples provided herein, interaction may be described in terms of two, three, or four network elements. However, this has been done for purposes of clarity and example only. In certain cases, it may be easier to describe one or more of the functionalities of a given set of flows by only referencing a limited number of network elements. It should be appreciated that topologies illustrated in and described with reference to the accompanying FIGURES (and their teachings) are readily scalable and may accommodate a large number of components, as well as more complicated/sophisticated arrangements and configurations. Accordingly, the examples provided should not limit the scope or inhibit the broad teachings of the illustrated topologies as potentially applied to myriad other architectures.

It is also important to note that the steps in the preceding flow diagrams illustrate only some of the possible signaling scenarios and patterns that may be executed by, or within, communication systems shown in the FIGURES. Some of these steps may be deleted or removed where appropriate, or these steps may be modified or changed considerably without departing from the scope of the present disclosure. In addition, a number of these operations have been described as being executed concurrently with, or in parallel to, one or more additional operations. However, the timing of these operations may be altered considerably. The preceding operational flows have been offered for purposes of example and discussion. Substantial flexibility is provided by communication systems shown in the FIGURES in that any suitable arrangements, chronologies, configurations, and timing mechanisms may be provided without departing from the teachings of the present disclosure.

Although the present disclosure has been described in detail with reference to particular arrangements and configurations, these example configurations and arrangements may be changed significantly without departing from the scope of the present disclosure. For example, although the present disclosure has been described with reference to particular communication exchanges, aspects described herein may be applicable to other architectures.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 142 as it exists on the date of the filing hereof unless the words “means for” or “step for” are specifically used in the particular claims; and (b) does not intend, by any statement in the specification, to limit this disclosure in any way that is not otherwise reflected in the appended claims.

1. A method for pretraining a hyper model configured for use in predicting a state of power (SoP) of a vehicle battery, the method comprising:
performing electrochemical impedance spectroscopy (EIS) scans on a plurality of batteries having a set of similar operating characteristics to the vehicle battery, the EIS scans performed across various states of the vehicle battery; and
fitting parameters of the hyper model by applying an optimization technique to results of the EIS scans, the hyper model comprising a family of models that each define a voltage response of a respective cell from among a plurality of cells of the vehicle battery to a current profile over the various states of the vehicle battery.

2. The method according to claim 1, further comprising estimating the state of power (SoP) of the vehicle battery using the hyper model, the results of the EIS scans, operational constraints of the vehicle battery, and the various states of the vehicle battery used in the EIS scans.

3. (canceled)

4. (canceled)

5. The method according to claim 1, wherein the hyper model is a model reduced from a physics based model that maps physics representations of battery elements to the various states of the vehicle battery used in the EIS scans.

6. The method according to claim 1, wherein the hyper model is an adaptive filter inferred using a frequency response of an equivalent impedance of the vehicle battery learned using the EIS scans under the various states of the vehicle battery.

7. (canceled)

8. (canceled)

9. (canceled)

10. (canceled)

11. The method according to claim 1, wherein the hyper model is a family of equivalent circuit models (ECMs), and the method further comprises performing a smart initialization of a parameter fitting method by setting a series resistor R in an R-RC ECM model having the series resistor R in series with one or more RC parallel sub-circuits to a smallest observed impedance value, setting model parameters to determined values and holding the determined values fixed while scanning over a range based on a value of the series resistor R to identify a determined value that minimizes an objective function.

12. A method for predicting a state of power (SoP) of a battery, the method comprising:
performing a plurality of electrochemical impedance spectroscopy (EIS) scans on the battery prior to an initial use of the battery in a vehicle;
calibrating a pretrained hyper model using results of the plurality of EIS scans, the hyper model comprising a family of models that each define a voltage response of a respective cell from among a plurality of cells of the battery to a current profile over various states of the batterys;
performing a plurality of additional EIS scans on the battery subsequent to the initial use of the battery in the vehicle;
recalibrating the pretrained hyper model using results of the plurality of additional EIS scans;
predicting the SoP of each of multiple cells of the vehicle battery responsive to a current battery state of each of the multiple cells;
combining the SoP of each of multiple cells into a battery SoP; and
controlling an amount of current extracted from or put into the battery responsive to a SoP value.

13. The method according to claim 12, wherein the plurality of additional EIS scans are periodically performed subsequent to the initial use of the battery in the vehicle.

14. (canceled)

15. (canceled)

16. The method according to claim 12, wherein the hyper model is a model reduced from a physics based model that maps physics representations of battery elements to the various states of the battery used in the EIS scans.

17. The method according to claim 12, wherein the hyper model is an adaptive filter inferred using a frequency response of an equivalent impedance of the battery learned using the EIS scans under the various states of the battery used in the EIS scans.

18. (canceled)

19. The method according to claim 12, wherein the hyper model is a family of equivalent circuit models (ECMs), and the method further comprises performing a smart initialization of a parameter fitting method by setting a series resistor R in an R-RC ECM model having the series resistor R in series with one or more RC parallel sub-circuits to a smallest observed impedance value, setting model parameters to determined values and holding the determined values fixed while scanning over a range based on a value of the series resistor R to identify a determined value that minimizes an objective function.

20. (canceled)

21. The method according to claim 12, wherein the plurality of addition EIS scans is performed while the battery is in key-on condition, the method further comprising, during a key-on condition of the battery:
measuring a current output from each of multiple cells of the battery; and
determining the current battery state of each of the multiple cells of the battery responsive to the current output from each of the multiple cells of the battery.

22. The method according to claim 12, further comprising predicting the SoP of at least one of the cells of the battery, wherein at least one constraint comprises at least one of a terminal voltage of the battery, a current of the battery, a temperature of the battery, and a state of charge (SoC) of the battery.

23. The method according to claim 12, wherein the plurality of additional EIS scans is performed while the battery is in a key-off condition to update the hyper model,
wherein in a key-off condition, the battery SoP is estimated using a regression algorithm given EIS measurements and a current state of the battery.

24. (canceled)

25. The method according to claim 12, wherein the SoP comprises a maximum allowable static current that can be sustained for a given time period.

26. The method according to claim 25, wherein the maximum allowable static current comprises a level of current that does not cause a constraint violation.

27. The method according to claim 25, wherein the maximum allowable static current comprises a level of current that does not result in a temporary loss of capacity of more than a specified fraction over a given time period.

28. (canceled)

29. (canceled)

30. The method according to claim 20, further comprising tracking a battery state including a terminal voltage of the battery using an Extended Kalman filter (EKF) technique that comprises predicting a battery state vector using a state space model and predicting the terminal voltage of the battery response over a desired period of time.

31. The method according to claim 30, wherein the EKF technique comprises forming battery system matrices expressed as a function of a step index that is dependent on parameters of the hyper model that, in turn, are dependent on the various states of the battery.

32. (canceled)

33. (canceled)

34. (canceled)

35. (canceled)

36. The method according to claim 12, wherein the SoP of the battery is equal to one of the SoPs of each of multiple cells.

37. The method according to claim 12, wherein the SoP value of a battery is equal to a lowest value from among the multiple cell SoPs for the multiple cells that constitute the battery.

38. (canceled)

39: A system for predicting a state of power (SoP) of a battery, the system comprising:
an electrochemical impedance spectroscopy (EIS) system for performing a plurality of EIS scans on the battery prior to an initial use of the battery in a vehicle, and a plurality of additional EIS scans on the battery in the vehicle;
a memory device for storing program code; and
a processing device operatively coupled to the EIS system and the memory device for running the program code to:
calibrate a pretrained hyper model using results of the plurality of EIS scans, the pretrained hyper model comprising a family of models that each define a voltage response of a respective cell from among a plurality of cells of the battery to a current profile over various states of the battery;
recalibrate the pretrained hyper model using results of the plurality of additional EIS scans;
predict the SoP of each of multiple cells of the vehicle battery responsive to a current battery state of each of the multiple cells;
combine the SoPs of each of multiple cells into a battery SoP; and
control an amount of current extracted from or put into the battery responsive to at least one of the SoPs of each of multiple cells or the battery SoP.

40. The system according to claim 39, wherein the system is comprised in a battery management system.

41. The system according to claim 39, wherein the plurality of additional EIS scans are periodically performed subsequent to the initial use of the battery in the vehicle.
